(19) United States
(12) Patent Application Publication
(10) Pub. No.: US 2024/0155790 A1
(43) Pub. Date: May 9, 2024

(54) BIMETAL RETAINING MECHANISMS FOR USE IN ELECTRONIC DEVICES

(71) Applicant: Intel Corporation, Santa Clara, CA (US)

(72) Inventors: Deepak Sekar, Bangalore (IN); Samarth Alva, Bangalore (IN); Prakash Kurma Raju, Bangalore (IN); Prasanna Pichumani, Bangalore (IN); Arnab Sen, Bangalore (IN)

(21) Appl. No.: 18/544,694

(22) Filed: Dec. 19, 2023

(51) Int. Cl. H05K 5/02; F16B 2/20; H05K 9/00

(52) U.S. Cl. CPC H05K 5/0221; F16B 2/20; H05K 9/0024; H05K 9/0049

(57) ABSTRACT

Techniques are described to address issues for repairing and/or servicing electronic components through the use of retaining assemblies that use bimetal retaining mechanisms. The bimetal retaining mechanisms may comprise various shapes such as hooks, snap-hooks, clips, etc., and facilitate a temperature-selective removal of various electronic components such as displays, EMI shields, etc. without damaging these components and without compromising the thickness and weight of the electronic device. External heating systems may be used to trigger actuation of the bimetal retaining mechanisms, resulting in their release. Alternatively, internal electronic device heating systems may be used.

### TECHNICAL FIELD

The disclosure is directed generally to a mechanical retaining system for electronic components and, in particular, to a temperature-selective bimetal mechanical retaining system that releases electronic components as a result of mechanical actuation when a temperature of the bimetal material is increased beyond a threshold temperature.

### BACKGROUND

Electronic devices often utilize various types of electronic components that are mechanically retained in a fixed physical relationship with other components. This may include displays that are bonded to the chassis of an electronic device such as a laptop or tablet. Additionally, electromagnetic interference (EMI) shields may comprise shield lids or gaskets, which cover components known to emit EMI. In each of these cases, the electronic components are typically bonded to their respective components via an adhesive and/or fastening system. These conventional mounting solutions have drawbacks in that repairs are more arduous and more likely to result in damage to the electronic components. As a result, conventional solutions also introduce issues of sustainability by increasing electronic waste.

### BRIEF DESCRIPTION OF THE DRAWINGS/FIGURES

The accompanying drawings, which are incorporated herein and form a part of the specification, illustrate the present disclosure and, together with the description, further serve to explain the principles and to enable a person skilled in the pertinent art to make and use the techniques discussed herein.

In the drawings, like reference characters generally refer to the same parts throughout the different views. The drawings are not necessarily to scale, emphasis instead generally being placed upon illustrating the principles of the disclosure. In the following description, reference is made to the following drawings, in which:

FIG. 1 illustrates a conventional display mounting solution;

FIG. 2A illustrates a bimetal retaining mechanism, in accordance with the disclosure;

FIG. 2B illustrates a bimetal actuation process, in accordance with the disclosure;

FIG. 3A illustrates a first bimetal retaining mechanism, in accordance with the disclosure;

FIG. 3B illustrates a second bimetal retaining mechanism, in accordance with the disclosure;

FIG. 3C illustrates part of a retaining assembly that shows a bimetal strip including several bimetal retaining mechanisms, in accordance with the disclosure;

FIG. 4A illustrates a electromagnetic interference (EMI) shield assembly, in accordance with the disclosure;

FIG. 4B illustrates a PCB-mounted temperature-selective mechanical retaining assembly, in accordance with the disclosure;

FIG. 4C illustrates various clip-shaped bimetal retaining mechanisms, in accordance with the disclosure;

FIGS. 5A and 5B illustrate the use of an indirect heating element in an off and on state, respectively, in accordance with the disclosure;

FIGS. 6A and 6B illustrate a direct heating element in an off and on state, respectively, in accordance with the disclosure;

FIG. 7A illustrates a table of bimetal alloys and their respective properties, in accordance with the disclosure;

FIG. 7B illustrates a graph of flexivity versus thermal deflection for various bimetal alloys, in accordance with the disclosure;

FIG. 8 illustrates an electronic device, in accordance with the disclosure; and

FIG. 9 illustrates a process flow, in accordance with the disclosure.

The present disclosure will be described with reference to the accompanying drawings. The drawing in which an element first appears is typically indicated by the leftmost digit(s) in the corresponding reference number.

### DETAILED DESCRIPTION

The following detailed description refers to the accompanying drawings that show, by way of illustration, exemplary details in which the disclosure may be practiced. In the following description, numerous specific details are set forth in order to provide a thorough understanding of the present disclosure. However, it will be apparent to those skilled in the art that the various designs, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring the disclosure.

I. Technology Overview

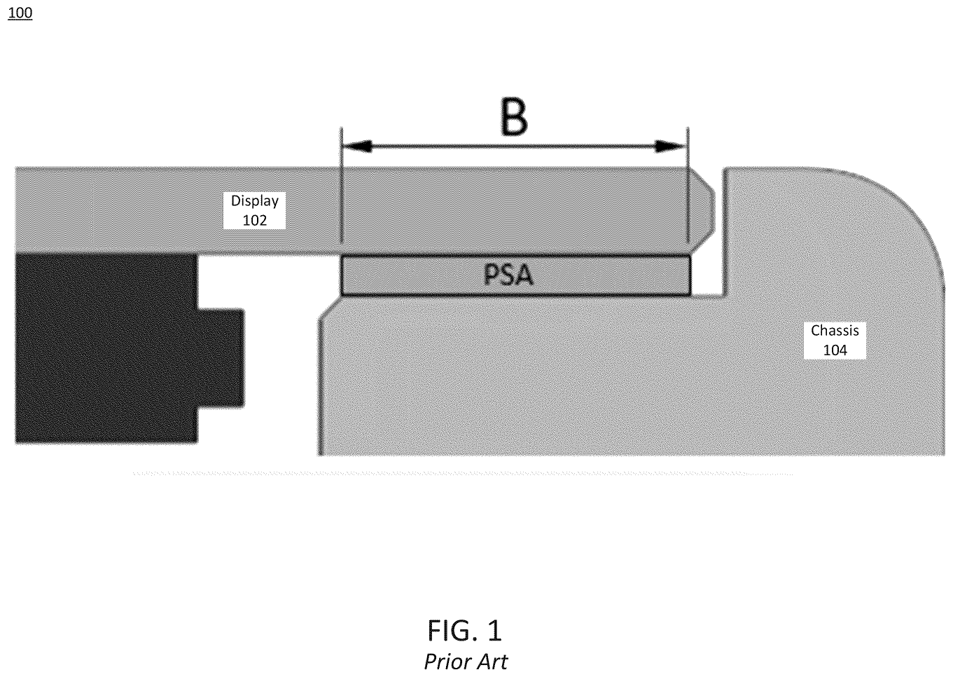

Again, conventional mechanical retaining systems for electronic components have drawbacks in that, once assembled, it is difficult to subsequently separate the electronic components for repairs or servicing without damaging the electronic components. As one example, displays in tablets, mobile phones, laptops, etc., are generally bonded to the device chassis. This may include the use of a pressure-sensitive adhesive (PSA), as shown in FIG. 1, which is applied to an outer border ‘B’ of the display screen 102 to bond the display screen 102 to the chassis 104. Although this fixed arrangement firmly retains the display screen 102 to the electronic device, the removal of the display screen 102 (e.g. for repair) is challenging, and the display screen 102 often breaks during removal. This leads to replacement of the entire display panel, which increases the costs for the end user and leads to the generation of e-waste.

Other conventional display mounting implementations include the use of a plastic snap fit arrangement, which includes a number of screws for locking. This provides further flexibility to perform repairs, but comes with a compromise on the thickness of system and the need for additional space. Suction cups are typically used for the removal of displays mounted in this manner, although display damage is still not eliminated.

Moreover, electronic devices often implement other retained electronic components such EMI shields, which may be very thin and are generally snap-fitted or clip-joined to a fence that is then soldered to a printed circuit board (PCB) of the electronic device. EMI shield lids mounted in this manner often become damaged during service and are replaced with new parts. To help prevent this damage, EMI gaskets or thicker shield lids may be used. However, EMI gaskets have a compressibility requirement to ensure complete EMI isolation, which complicates their use. For instance, the load for attaining minimum compressibility for thin EMI gaskets is relatively high, and thus requires additional mounting holes on the PCB to provide uniform compression of gasket. Thus, the use of conductive gasket for EMI shielding requires force to maintain minimum compression, which results in additional mounting holes required on the PCB. Furthermore, thicker EMI gaskets require less load for compression, but increase the device thickness. The removal of these EMI shields during repair often damages these parts and/or the parts to which the EMI shields are coupled, which results in the replacement of these components. Again, this increases the costs to customers and results in e-waste.

II. Temperature-Selective Bimetal Retaining Assemblies

Again, conventional solutions for mounting electronic components do not allow for easy repairability, and result in either the replacement of parts or designing bulkier electronic devices by compromising the system thickness. With this in mind, the techniques described herein address these issues through the use of retaining assemblies that use bimetal retaining mechanisms. As discussed in further detail below, these retaining assemblies may comprise any suitable arrangement and/or shape of bimetal retaining mechanisms, such as hooks, snap-hooks, clips, etc., which facilitate the separation and/or removal of various electronic components such as displays, EMI shields, etc. without damaging these components and without compromising the thickness and weight of the electronic device in which the retaining assemblies are implemented.

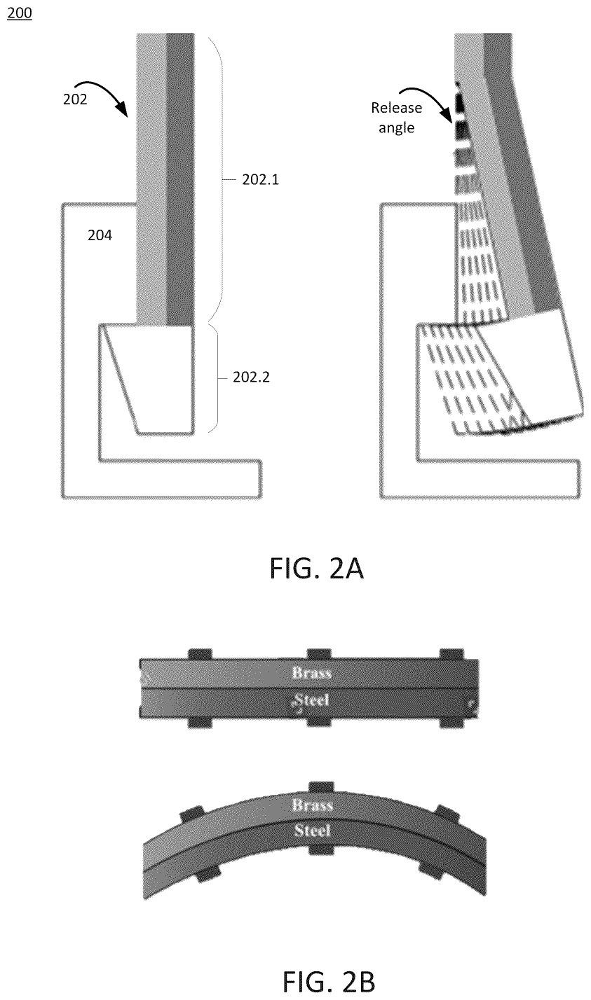

FIG. 2A illustrates a bimetal retaining mechanism, in accordance with the disclosure. As shown in FIG. 2A, the bimetal retaining mechanism 202 comprises a bimetal portion 202.1 and a retaining portion 202.2. The portions 202.1, 202.2 are shown as separate portions in FIG. 2A for ease of explanation and to highlight the functionality of the bimetal material. However, the portions 202.1, 202.2 may be integrated as part of the same retaining mechanism 202, as further discussed herein, such that the entire retaining mechanism 202 is formed of the same bimetal material. Alternatively, the portions 202.1, 202.2 may be formed of different materials. This may include the portion 202.1 being formed of a bimetal material and the portion 202.2 being formed of a non-bimetal material that is bonded or otherwise coupled to the bimetal portion 202.1.

In any event, it is noted that the bimetal material associated with the bimetal retaining mechanism 202 may comprise any suitable material and may be of any suitable shape, which is composed of two separate metals joined together as shown in FIG. 2A. It is noted that bimetal is a composite material made up of two or more metallic layers having different coefficients of thermal expansion. As a result, when permanently bonded together, these layers cause the bimetal material to bend/change its curvature when subjected to a change in temperature, which is shown in further detail in FIG. 2B. This change of curvature, or bending, in response to temperature change is a fundamental property of all bimetals.

In the non-limiting and illustrative scenario as showing in FIGS. 2A-2B, the bimetal material of the bimetal retaining mechanism 202 comprises brass and steel. But regardless of the particular metals that are implemented, the bimetal retaining mechanism 202 is sensitive to operating temperatures and will change its shape when the bimetal material exceeds a predetermined threshold temperature, which may be alternatively referred to as a transition temperature. Thus, and as further discussed herein, the bimetal retaining mechanism 202 may convert a temperature change into mechanical actuation, resulting in a mechanical displacement.

This mechanical actuation is shown in further detail on the right side of FIG. 2A. Thus, as shown in the left side of FIG. 2A, the bimetal retaining mechanism 202 engages with a mechanical structure 204 of an electronic device, which may be a chassis of the electronic device in the current and illustrative scenario. As a result of this engagement, a fitted arrangement is formed between the bimetal retaining mechanism 202 and the mechanical structure 204. Thus, when a temperature of the bimetal retaining mechanism 202 is less than a predetermined threshold temperature (such as the transition temperature or a temperature exceeding the transition temperature), this fitted arrangement is maintained. In this “default” state, any electronic component to which the fitted arrangement is coupled (such as a display) is also captivated (i.e. retained) with respect to the mechanical structure 204.

However, when heated in excess of the predetermined threshold temperature, the bimetal retaining mechanism 202 is placed into an actuated state and thus released from the mechanical structure 204 to enable removal of the electronic component from the electronic device. This is shown in the right side of FIG. 2B, which illustrates that when the bimetal retaining mechanism 202 is heated and placed into the actuated state, a release angle is increased in excess of a threshold release angle value, thus facilitating the bimetal retaining mechanism 202 being released from the mechanical structure 204 as shown.

This may be the case, in a non-limiting and illustrative scenario, during repair of an electronic device that implements the bimetal retaining mechanism 202, and may include the use of any suitable heat source. Such a heat source may be used to raise the temperature at the location of the bimetal retaining mechanism 202 to deflect the bimetal retaining mechanism 202 via actuation as shown in FIG. 2B to assist in the removal of an electronic component without causing damage. As discussed in further detail below, these techniques may also be implemented to facilitate the release of any suitable type of electronic components, such as display screens, as well as EMI shield lids made of bimetal that may replace conventional EMI shield lids, which are typically steel.

An assembly in a production line using the bimetal EMI shield lid may thus advantageously remain the same as one currently used for assembling conventional EMI shield lids. Thus, during servicing, the bimetal EMI shield lid may be heated to cause deflection in the region of the bimetal retaining mechanism 202 to facilitate removal of the EMI shield lid without causing damage. Alternately, the bimetal retaining mechanism 202 may be implemented as one or more bimetal clips that are fixedly coupled (e.g. via solder) to a PCB to serve the same purpose of easy repairability.

The techniques discussed in further detail below may exploit this use of bimetal retaining mechanisms to facilitate the implementation of a temperature-selective mechanical retaining assembly, which may alternatively be referred to herein simply as a retaining assembly. Although such retaining assemblies are discussed herein with respect to displays and EMI shield components, it is noted that these are non-limiting and illustrative scenarios. Moreover, and as discussed in further detail below, the bimetal retaining mechanisms used for such retaining assemblies may comprise shapes in addition to or instead of the bimetal retaining mechanism 202.

Thus, the retaining assemblies as discussed in further detail below may be implemented using any suitable bimetal material having any suitable shape, which may be used to provide a temperature-selective mechanical retaining system for any suitable application and/or any suitable electronic components, which may differ from those described herein. Additionally, although described herein in terms of a bimetal material, this is also a non-limiting and illustrative scenario, and the bimetal retaining assembly as discussed herein may comprise the use of additional layers of different metals, such as trimetals, tetrametals, etc.

III. Bimetal Retaining Assemblies for the Removal of Displays

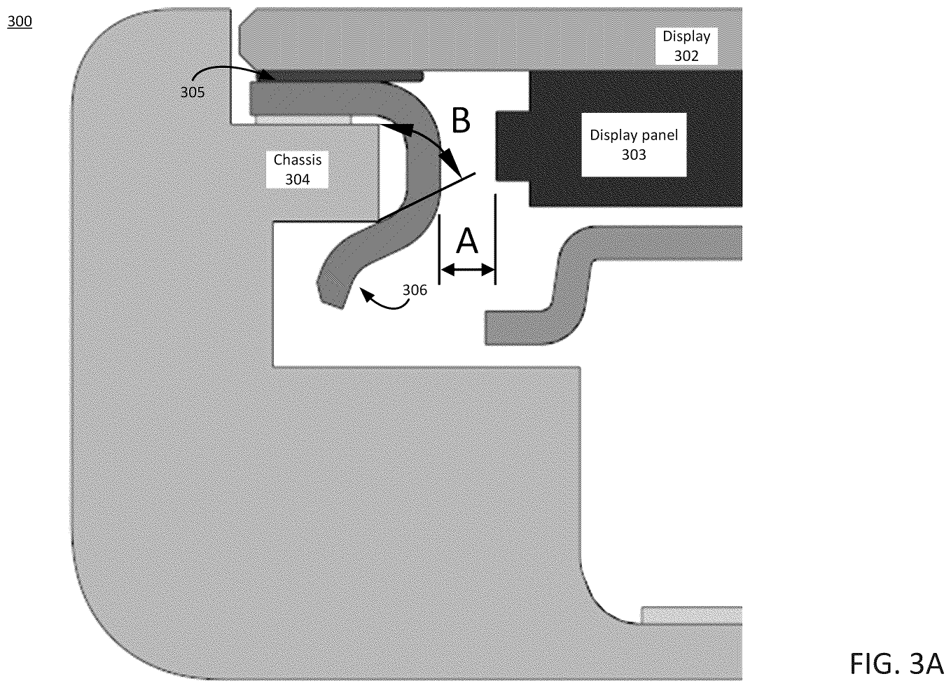

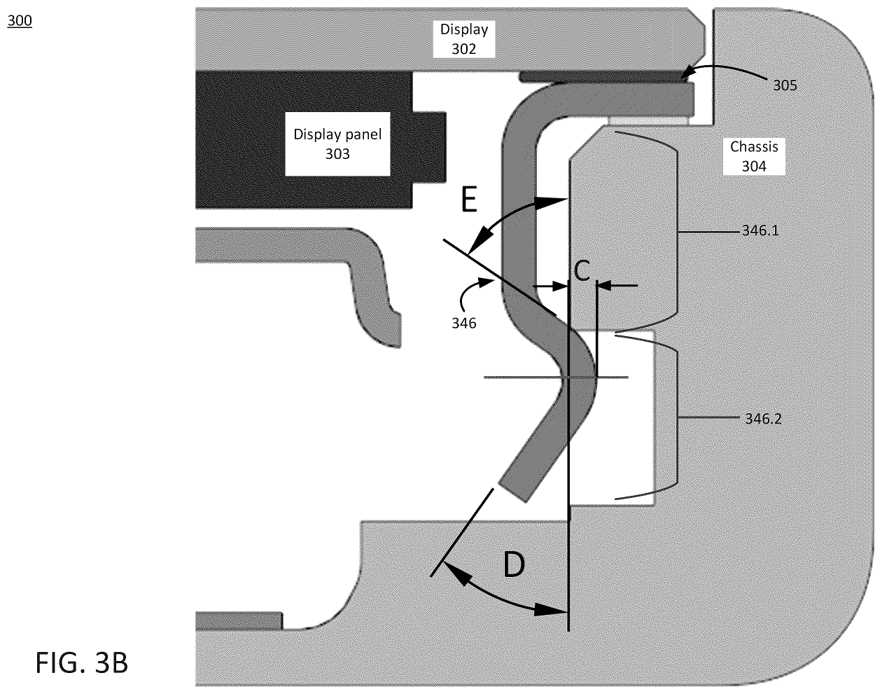

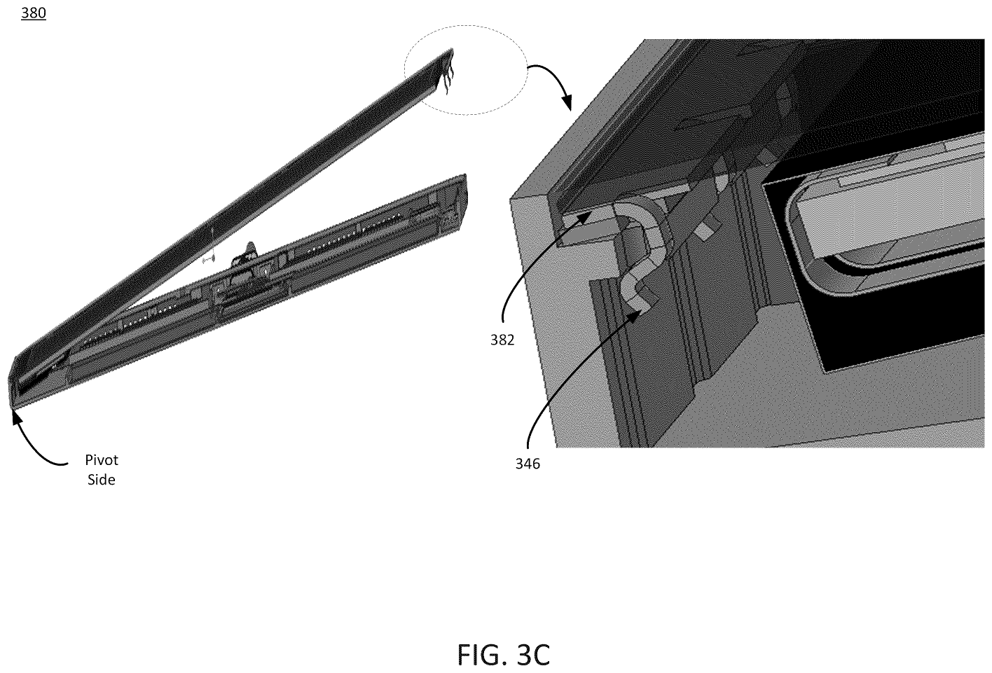

FIGS. 3A-3C are directed to the use of temperature-selective mechanical retaining assemblies within an electronic device. For each of the retaining assemblies as further discussed with respect with FIGS. 3A-3C, the retaining assemblies may comprise part of any suitable electronic device 300, such as a laptop, a tablet computer, etc. Thus, the temperature-selective mechanical retaining assembly described herein with respect to each of the FIGS. 3A-3C may be fixed to any suitable electronic component that is to be removed using a bimetal heating process, as discussed herein. The electronic component described in this Section with respect to a display screen, but may be extended to include any suitable number of additional or alternate electronic components.

FIGS. 3A and 3B illustrate a first and a second bimetal retaining mechanism, respectively, in accordance with the disclosure. The bimetal retaining mechanism 306 as shown in FIG. 3A may be referred to herein as a “hook,” which provides a fitted arrangement between the bimetal retaining mechanism 306 and the mechanical structure of the electronic device (shown in FIG. 3A as the chassis 304) via a snap-fit mechanical engagement between the hook and the mechanical structure. The bimetal retaining mechanism 346 as shown in FIG. 3B may be referred to herein as a “snap-hook” which also provides a fitted arrangement between the bimetal retaining mechanism 346 and the mechanical structure of the electronic device (shown in FIG. 3A as the chassis 304) via a snap-fit arrangement between the snap-hook and the mechanical structure.

The bimetal retaining mechanisms 306, 346 may be of any suitable size and/or shape depending upon the particular application, and thus the designs shown in FIGS. 3A-3B are non-limiting and illustrative. In any event, the bimetal retaining mechanisms 306, 346 may be part of a larger retaining assembly 382, an illustrative and non-limiting scenario of which is shown in further detail in FIG. 3C. Thus, and with reference to FIG. 3C, the retaining assembly 382 may be comprised completely or partially of any suitable type of bimetal material, have any suitable shape, and comprise any suitable number of bimetal retaining mechanisms, such as the bimetal retaining mechanisms 306, 346 as shown in FIGS. 3A and 3B. Thus, each of the bimetal retaining mechanisms 306, 346 as discussed herein may be formed as part of a respective retaining assembly 382 as shown in FIG. 3C, with a single bimetal retaining mechanism 306, 346 being shown in FIGS. 3A and 3B for ease of explanation.

To provide an illustrative and non-limiting scenario, the retaining assembly 382, which again may comprise any suitable number of bimetal retaining mechanisms 306, 346, may comprise any suitable number of bimetal strips as shown in FIG. 3C and/or alternate shapes. Thus, although a single strip is shown in FIG. 3C, the retaining assembly 382 may comprise any suitable number of such strips, such as one strip per side of the display 302. Moreover, the retaining assembly 382 may include bimetal strips having different types of bimetal retaining mechanisms depending upon the particular application and/or implementation of the bimetal retaining mechanisms as part of the mounting of the display 302 within the chassis 304 of the electronic device 300. Thus, although the retaining assembly 382 is shown in FIG. 3C as implementing a number of the bimetal retaining mechanisms 346 as shown in FIG. 3B, the retaining assembly 382 may additionally or alternatively comprise any suitable number of the bimetal retaining mechanisms 306 as shown in FIG. 3A. In one non-limiting and illustrative scenario, the retaining assembly 382 may include a single bimetal strip, with the bimetal retaining mechanisms 306 being implemented on one side of the display 302. Continuing this non-limiting and illustrative scenario, the retaining assembly 382 may include three additional bimetal strips, each having the bimetal retaining mechanisms 346 as shown in FIG. 3B, on the remaining three sides of the display 302. It is noted that although referred to as a “display,” it is recognized that the display 302 may form part of an overall display module or assembly, and thus although the term display is used herein, this may refer to the display screen or an entirety of the display assembly that is to be retained via the various bimetal retaining mechanisms as discussed herein.

This configuration may be particularly useful for a pivot-based design for installation. That is, the bimetal retaining mechanisms 306 may form part of a bimetal strip on the pivot side of the electronic device 300 as shown in FIG. 3C, which may form a pivot point for assembly and disassembly between the chassis 304 and the display 302. The bimetal retaining mechanisms 346 may form part of each of the bimetal strips on the remaining three sides of the electronic device 300, with one side being shown in further detail in FIG. 3C. In any event, the retaining assembly 382, which again may comprise any suitable number of bimetal strips, may be fixedly coupled to the display 302 as shown in FIG. 3A using any suitable means. This may include the use of a pressure-sensitive adhesive 305 as shown in FIGS. 3A-3B. Thus, the retaining assembly 382 may be permanently bonded to the display 302 while facilitating a temperature-selective fitted arrangement between each of the retaining mechanisms and the chassis 304.

Again, the bimetal retaining mechanisms of the retaining assembly 382 may be of any suitable size and/or shape, with the bimetal retaining mechanism 306 as shown in FIG. 3A comprising a hook shape that is configured to provide the fitted arrangement between the bimetal retaining mechanism 306 and the mechanical structure of the electronic device 300 via a mechanical engagement between the hook and the mechanical structure. Each bimetal retaining mechanism 306 of the retaining assembly 382 may have a similar or identical physical arrangement with the mechanical structure. For purposes of brevity, the functionality of a single bimetal retaining mechanism 306 is described, although it will be understood that the retaining assembly 382 may comprise any suitable number of bimetal retaining mechanisms 306, 346 that function in the same manner as that described herein for the bimetal retaining mechanism 306.

The retaining assembly 382 may thus comprise any suitable number of bimetal retaining mechanisms 306, 346 configured to retain the display 302 to the electronic device 300 by way of a fitted arrangement that is formed between each bimetal retaining mechanism 306, 346 and the mechanical structure of the electronic device 300. In the scenario as shown in FIG. 3A, this fitted arrangement is formed via a mechanical engagement between the hook of each bimetal retaining mechanism 306 and the mechanical structure. The mechanical structure is shown in FIG. 3A as the chassis 304 of the electronic device 300, although this is non-limiting and illustrative. This fitted arrangement ensures that the display 302 is retained to the electronic device 300 when the bimetal retaining mechanisms 306 are in their default or “undeformed” state, i.e. when the temperature of the bimetal retaining mechanism 306 is less than a predetermined threshold temperature, such as the transition temperature as noted above. However, due to their bimetal properties, each bimetal retaining mechanism 306, when heated in excess of the predetermined threshold temperature, is released from the mechanical structure of the electronic device 300.

The configuration of the bimetal retaining mechanisms in this manner ensures the removal of the electronic component (the display 302 in this case) from the electronic device 300 upon heating. Specifically, the bimetal retaining mechanism 306 may have a size and shape such that, when heated in excess of the threshold temperature, causes a mechanical actuation that results in a decoupling from the mechanical structure of the electronic device 300. Thus, it is noted that the fitted arrangement between each bimetal retaining mechanism 306 and the mechanical structure of the electronic device 300 is such that the metal having the larger coefficient of thermal expansion is disposed closer to the mechanical structure of the electronic device 300, i.e. opposite to the desired direction of bending upon heating.

To provide an illustrative and non-limiting scenario regarding the size and shape of the bimetal retaining mechanism 306, the dimension ‘A’ may represent a clearance between the bimetal retaining mechanism 306 and the display panel 303, which forms part of a display assembly that includes the display 302. A typical value for this clearance dimension A may be 0.50 mm Moreover, for the scenario as shown in FIG. 3A, the hook-shaped bimetal retaining mechanism 306 provides the fitted arrangement between the bimetal retaining mechanism 306 and the chassis 304 via a mechanical engagement between the hook-shape and the chassis 304. Again, this is the case when the bimetal retaining mechanism 306 in in its undeformed state.

Thus, in this undeformed state, the angle ‘B,’ which may be referred to herein as a retaining angle, may be greater than or equal to a threshold retaining angle. The retaining angle B may be complementary to an angle B′ (not shown), which may be referred to herein as a release angle. In the undeformed state, the retaining angle B is greater than or equal to the threshold retaining angle, whereas the release angle B′ is less than or equal to a threshold release angle. When the temperature of each bimetal retaining mechanism 306 exceeds the threshold temperature as noted above, the retaining angle B decreases to less than the threshold retaining angle while its complement, the release angle B′, increases to greater than the threshold release angle. In this way, the fitted arrangement between the bimetal retaining mechanisms 306 and the mechanical structure of the electronic device 300 is maintained by way of the release angle being less than the threshold release angle. When heated in excess of the predetermined threshold temperature, the release angle of each bimetal retaining mechanism 306 is thus increased to greater than the threshold release angle as a result of mechanical actuation.

Turning now to FIG. 3B, the retaining mechanism 346 comprises a snap-hook that includes a hook portion 346.1 and a snap portion 346.2. The retaining mechanism, 346 thus functions in a similar manner as the hook retaining mechanism 306 as shown in FIG. 3A, and the above description with respect to the retaining mechanism 306 also applies to the retaining mechanism 346 except where noted otherwise. In particular, the hook portion 346.1 functions in the same manner as the hook shaped retaining mechanism 306. However, the retaining mechanism 346 also includes the additional snap portion 346.2, such that the fitted arrangement between the bimetal retaining mechanism 346 and the mechanical structure is made via a snap fit mechanical engagement between the snap-hook and the mechanical structure.

The snap-hook shaped retaining mechanism 346 may be implemented for applications in which a larger (such as thicker) mechanical structure is implemented compared to the hook-shaped retaining mechanism 306. Additionally, it may be preferable to use the snap-hook shaped retaining mechanism 346 versus the hook-shaped retaining mechanism 306 depending upon the particular location of the retaining assembly 382 and/or the manner in which the electronic component is installed. That is, the hook-shaped retaining mechanism 306 may be used on a pivot side of the display 302, whereas the snap-hook shaped retaining mechanism 346 may be used for one or more other sides of the display 302, as noted above.

Again, the mechanical structure is shown in FIG. 3A as the chassis 304 of the electronic device 300, although this is a non-limiting and illustrative scenario. As noted above with respect to the bimetal retaining mechanism 306, this fitted arrangement ensures that the display 302 is retained to the electronic device 300 when the bimetal retaining mechanism 346 is in a default or “undeformed” state, i.e. when the temperature of the bimetal retaining mechanism 346 is less than a predetermined threshold temperature, such as the transition temperature as noted above. But when heated in excess of the predetermined threshold temperature, each bimetal retaining mechanism 346 is likewise released from the mechanical structure of the electronic device 300.

To provide an illustrative and non-limiting scenario regarding the size and shape of the bimetal retaining mechanism 346, the dimension ‘C’ may represent a dimension of mechanical engagement between the snap portion 346.2 and the chassis 304 to form part of the snap-fit mechanical engagement. A typical value for this clearance dimension A may be 0.30 mm Moreover, the snap-hook-shaped bimetal retaining mechanism 346 further provides the snap-fit mechanical engagement via the hook portion 346.1 and the chassis 304. Typical values for the angles D and E may comprise 55 degrees and 35 degrees, respectively.

Thus, in this state, the angle D may be referred to as a release angle, whereas the angle E may be referred to herein as a retaining angle. The retaining angle E may, in the undeformed state, be greater than or equal to a threshold retaining angle, whereas the release angle D may be less than or equal to a threshold release angle. When the temperature of each bimetal retaining mechanism 346 exceeds the threshold temperature as noted above, the retaining angle E decreases to less than the threshold retaining angle while the release angle D increases to greater than the threshold release angle. In this way, the fitted arrangement between the bimetal retaining mechanisms 346 and the mechanical structure of the electronic device 300 is maintained by way of the release angle D being less than the threshold release angle and the retaining angle being E being greater than a threshold retaining angle. When heated in excess of the predetermined threshold temperature, the release angle D of each bimetal retaining mechanism 346 is thus increased to greater than the threshold release angle while the retaining angle E is decreased to less than the threshold retaining angle as a result of mechanical actuation.

IV. The Use of Bimetal Retaining Mechanisms for Other Types of Electronic Components

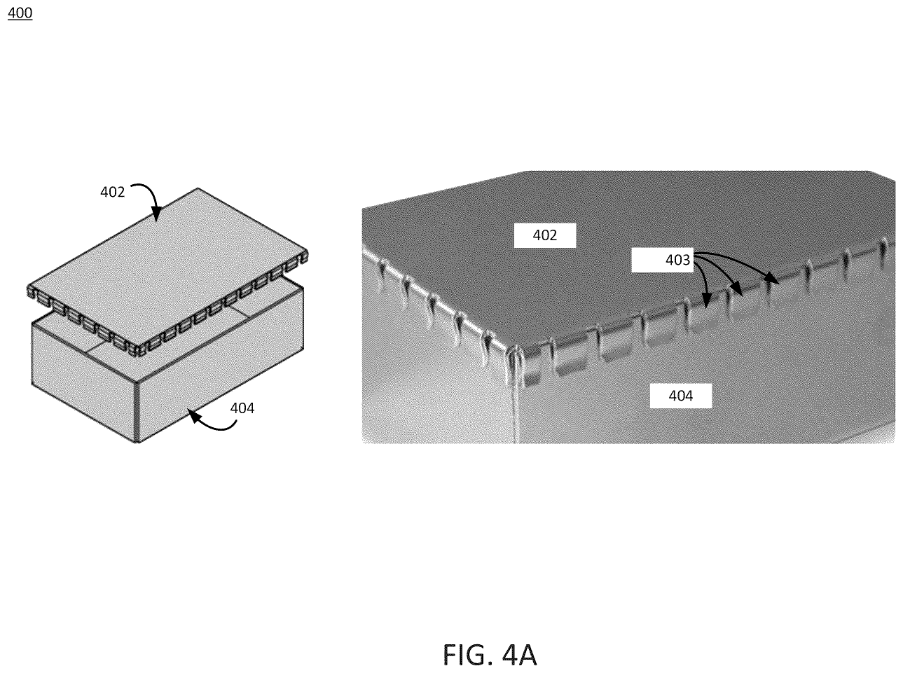

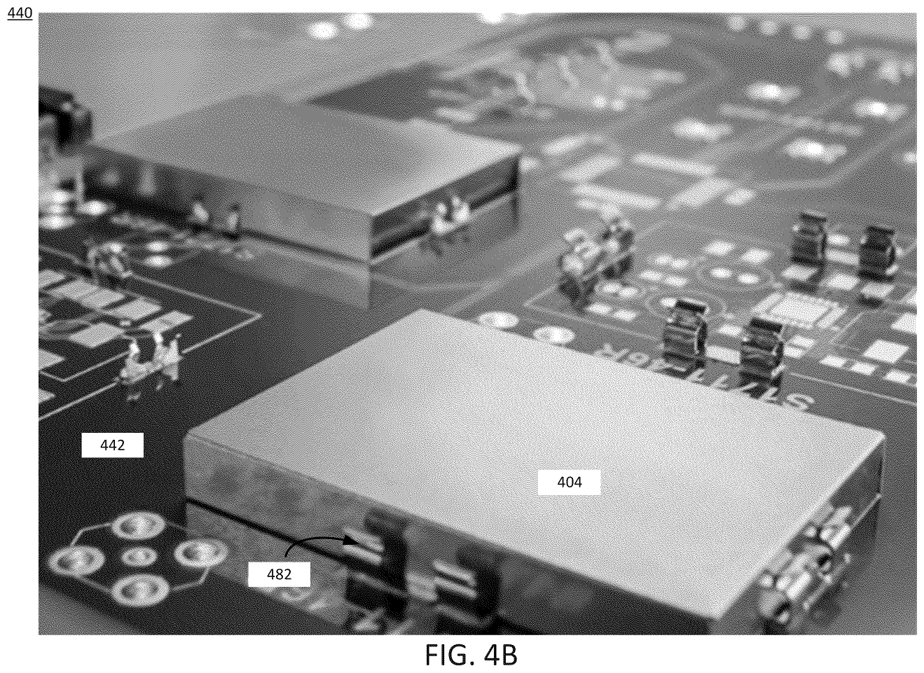

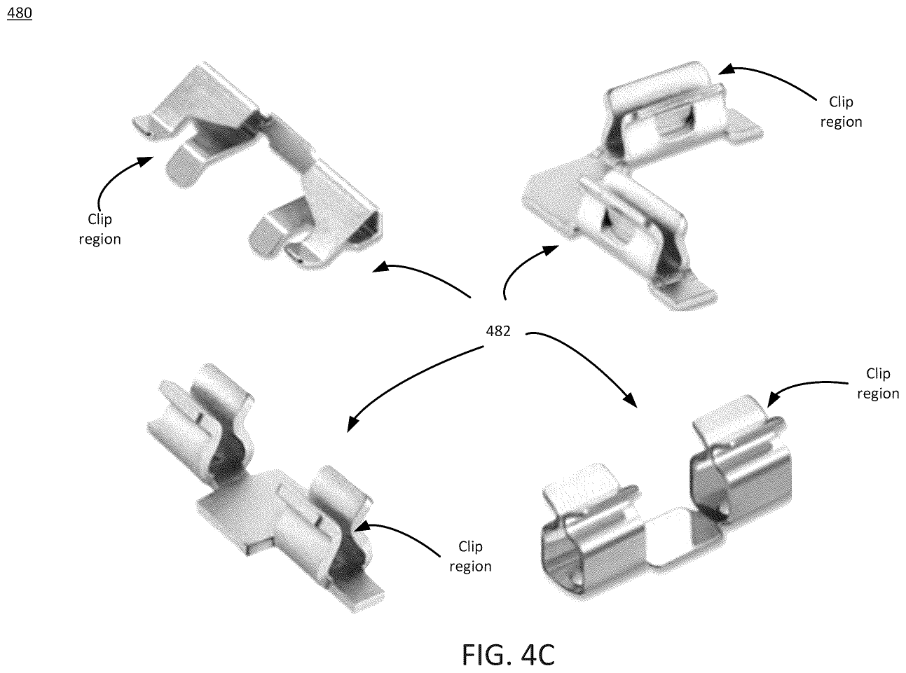

Again, the use of the bimetal retaining mechanisms described herein is not limited to electronic displays, and may facilitate the temperature-selective removal of any suitable type of electronic component by way of mechanical actuation as discussed in further detail herein. To this end, FIG. 4A illustrates a electromagnetic interference (EMI) shield assembly 400, in accordance with the disclosure. The EMI shield assembly 400 as shown in FIG. 4A comprises a removable EMI cover 402 and an EMI housing 404, which may be in a fitted arrangement with one another in a default (i.e. non-heated) state.

The removable EMI cover 402 may be comprised of any suitable bimetal material as discussed herein, and may comprise any suitable number of bimetal retaining mechanisms 403 as shown. The removable EMI cover 402 and the bimetal retaining mechanisms 403 may be integrated into a common component as shown in FIG. 4A, and thus the entirety of the removable EMI cover 402 may be comprised of a bimetal material. Alternatively, the bimetal retaining mechanisms 403 may be comprised of a bimetal material and the removable EMI cover 402 may be comprised of a different, non-bimetal material, which are bonded or otherwise coupled to one another to form a single, integrated component. The bimetal retaining mechanisms 403 may also be of any suitable shape, such as a clip-shaped bimetal retaining mechanisms 482 as shown in FIG. 4C, the hook-shaped bimetal retaining mechanism 306 of FIG. 3A, or the snap-hook shaped bimetal retaining mechanism 346 of FIG. 3B. Thus, although only one side of the bimetal retaining mechanisms 403 is illustrated in the Figures, the bimetal retaining mechanisms 403 may have another side and form a clip or other suitable shape having a retaining region that is smaller than the thickness of the EMI housing 404 and configured to retain the edge of EMI housing 404 by way of mechanical tension.

The EMI housing 404 may alternatively be referred to as an EMI shield, and may be comprised of any suitable type of conductive materials, such as bi-metals or non-bimetals. The EMI housing 404 may be implemented as any suitable shape, and may be formed of a solid sheet, a screen, a perforated metal, etc. Either of the removable EMI cover 402 or the EMI housing 404 may be coupled to any suitable components of the electronic device 300, such as a PCB. Thus, one of the removable EMI cover 402 or the EMI housing 404 may be soldered or otherwise bonded to a PCB or other suitable electronic components, whereas the other one of the removable EMI cover 402 or the EMI housing 404 may be removable via a heating process as discussed above.

Thus, the EMI housing 404 is coupled to the removable EMI cover 402 via a fitted arrangement between the bimetal retaining mechanisms 403 and the removable EMI cover 402. This fitted arrangement may be maintained when the temperature of the bimetal retaining mechanisms 403 is less than a predetermined threshold temperature, such as the transition temperature as discussed above. However, when the bimetal retaining mechanisms 403 are heated in excess of the predetermined threshold temperature, the bimetal retaining mechanisms 403 are released from the EMI housing 404. This release is a result of the mechanical actuation of the bimetal retaining mechanisms 403 that results in an outward bending of the bimetal retaining mechanisms 403 to exceed a threshold release angle to reduce the tension of the fitted arrangement, similar to the bimetal retaining mechanisms 306, 346 as discussed above. This enables the removal of the separation of the removable EMI cover 402 and the EMI housing 404. Again, this separation by way of the application of heat may be particularly advantageous for repairs or servicing, which allows for the reuse of these components.

FIG. 4B illustrates a temperature-selective mechanical retaining assembly, in accordance with the disclosure. The temperature-selective mechanical retaining assembly 440 as shown in FIG. 4B also includes an EMI housing 404 as discussed above, which again may be referred to as an EMI shield. However, instead of the removable EMI cover 402, the temperature-selective mechanical retaining assembly 440 includes any suitable number of bimetal retaining mechanisms 482, which are shown in further detail in FIG. 4C. The bimetal retaining mechanisms 482 may be entirely or partially comprised of any suitable type of bimetal material, and have any suitable size and shape to accommodate the EMI housing 404 via a tension fitted arrangement. Thus, the bimetal retaining mechanisms 482 may comprise clips that function to retain the EMI housing 404 when in their default (i.e. non-heated) state via insertion of the edge (i.e. the thickness dimension) of the EMI housing 404 into the clip region as shown in FIG. 4C.

Thus, each of the bimetal retaining mechanisms 482 may be fixedly coupled to an electronic component of the electronic device 300. In the non-limiting and illustrative scenario as shown in FIG. 4B, the electronic component comprises a PCB 442, and the bimetal retaining mechanisms 482 may be fixedly coupled to the PCB 442 via solder, adhesive, etc. In this configuration, the bimetal retaining mechanisms 482, when heated in excess of the predetermined threshold temperature, are released from the EMI housing 404 via mechanical actuation as discussed above, which “opens” the clips and decreases the mechanical tension between the bimetal retaining mechanisms 482 and the EMI housing 404. This enables a separation and removal of the EMI housing 404 from the PCB 442 of the electronic device 300.

V. Integrated Heating Systems

Any of the bimetal retaining mechanisms as discussed herein may facilitate a temperature-selective release of various types of electronic components of the electronic device 300. The heat used to bring the bimetal retaining mechanisms to their threshold temperatures to cause mechanical actuation for this purpose may be generated via any suitable heat source. For instance, an external heat gun may be used for this purpose. However, in various non-limiting and illustrative scenarios, which are further described below, it may be particularly advantageous to incorporate heating elements as part of the electronic device 300, which may include the use of indirect and/or direct heating elements.

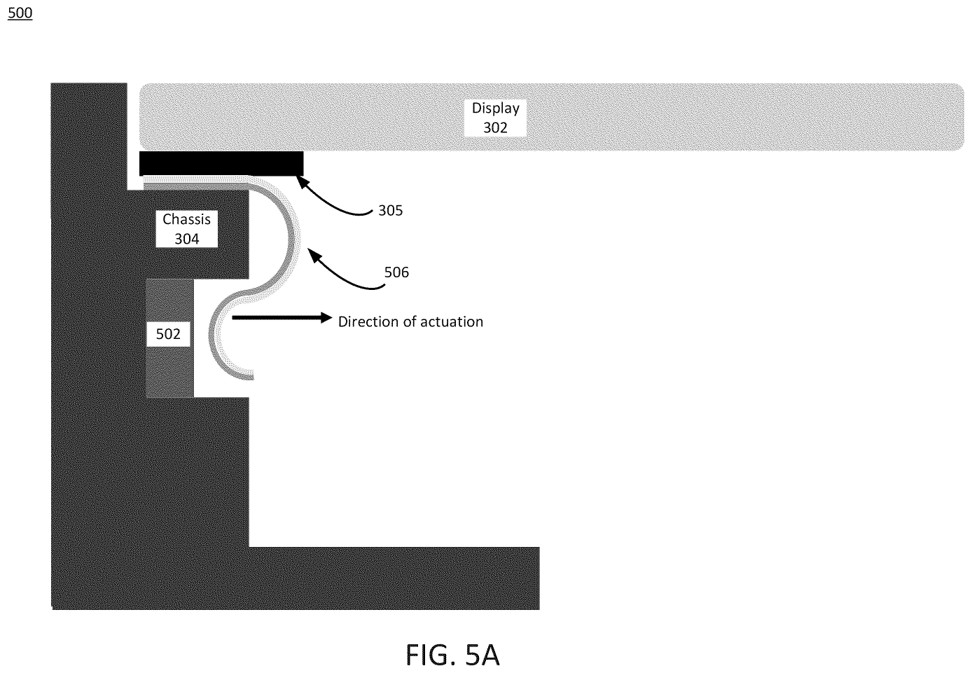

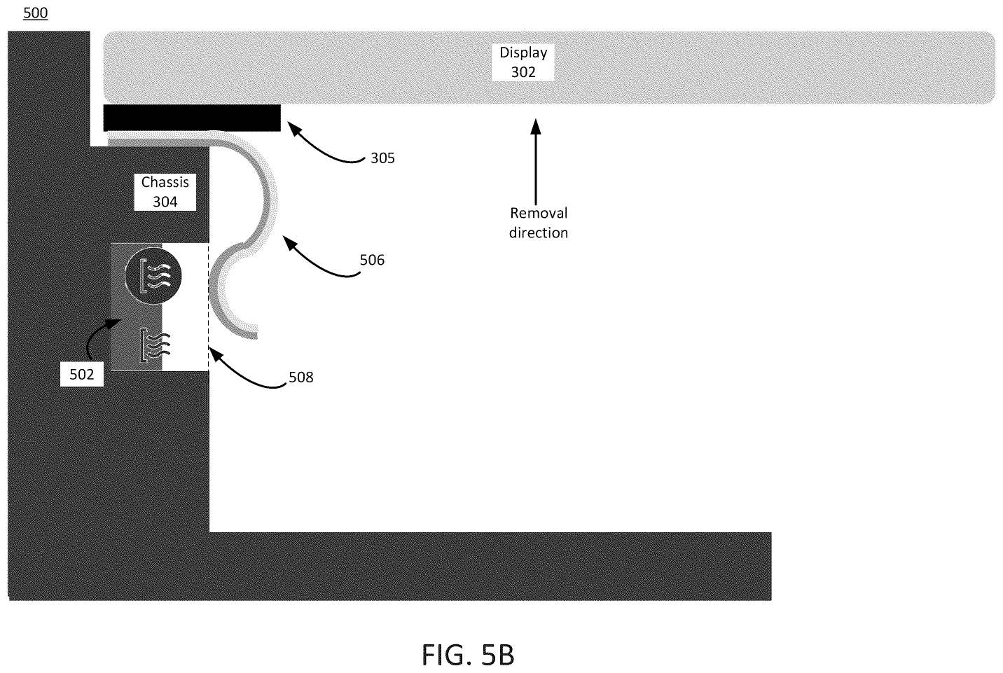

FIGS. 5A and 5B illustrate the use of an indirect heating element in an off and an on state, respectively, in accordance with the disclosure. The electronic device 500 as shown in FIGS. 5A-5B may be identified with the electronic device 300 as discussed herein, and thus may include any suitable number of bimetal retaining mechanisms 506. The bimetal retaining mechanisms 506 may be identified with any of the bimetal retaining mechanisms as discussed herein, such as the bimetal retaining mechanisms 306, 346, the bimetal retaining mechanisms 403 included as part of the removable EMI cover 402, the bimetal retaining mechanisms 482, etc.

The electronic device 500 may further comprise any suitable number of indirect heating elements 502, with one being shown in FIGS. 5A-5B for purposes of brevity. Each indirect heating element 502 may be implemented as any suitable type of component that is configured to selectively generate heat in the proximity of (such as between 0.5 mm to 10 mm) one or more bimetal retaining mechanisms 506 when predetermined activation conditions have been met, as discussed in further detail herein. Each indirect heating element 502 may be coupled to the mechanical structure of the electronic device 500 (such as to the chassis 304 as shown) and is configured to provide indirect heating to one or more of the bimetal retaining mechanisms 506 that form part of a larger retaining assembly as noted above. Each indirect heating element 502 may comprise one or more layers of thermal insulation or be coupled to the chassis 304 via layers of thermal insulation. This arrangement prevents the chassis 304 from sinking excessive heat when the indirect heating element 502 is in the on state, thus ensuring adequate heating of the bimetal retaining mechanisms 506 while protecting the other components of the electronic device 500.

In an illustrative and non-limiting scenario, the indirect heating elements 502 may comprise ceramic heating elements, and may be configured to generate heat in response to control signals (not shown) that are provided by one or more electronic components of the electronic device 300 that are configured for this purpose. The indirect heating elements 502 may transition between the off state as shown in FIG. 5A and the on state as shown in FIG. 5B in response to these received control signals. Thus, the predetermined conditions may comprise user input that is provided in various ways, as discussed in further detail below.

The indirect heating elements 502 may be disposed within the electronic device 300 at locations proximate to (such as between 0.5 mm to 10 mm) one or more respective bimetal retaining mechanisms 506. The indirect heating elements 502 may be disposed in the electronic device 300 in a one-to-one relationship with each of the bimetal retaining mechanisms 506 or, alternatively, the indirect heating elements 502 may be disposed proximate to (such as between 0.5 mm to 10 mm) more than one bimetal retaining mechanism 506. In any event, the indirect heating elements 502 are configured, when activated, to heat one or more bimetal retaining mechanisms 506 in excess of a predetermined threshold temperature. In response, each bimetal retaining mechanisms 506 may be actuated in a direction of actuation, as shown in FIG. 5B, which illustrates the heating element 502 in the on state and the corresponding actuated mechanical position of the bimetal retaining mechanism 506. As shown in FIG. 5B, upon actuation of the bimetal retaining mechanism 506, the hook portion now “clears” the chassis 304 with respect to the vertical direction as shown by the reference line 508, which allows for the removal of the display 302 in the removal direction as shown.

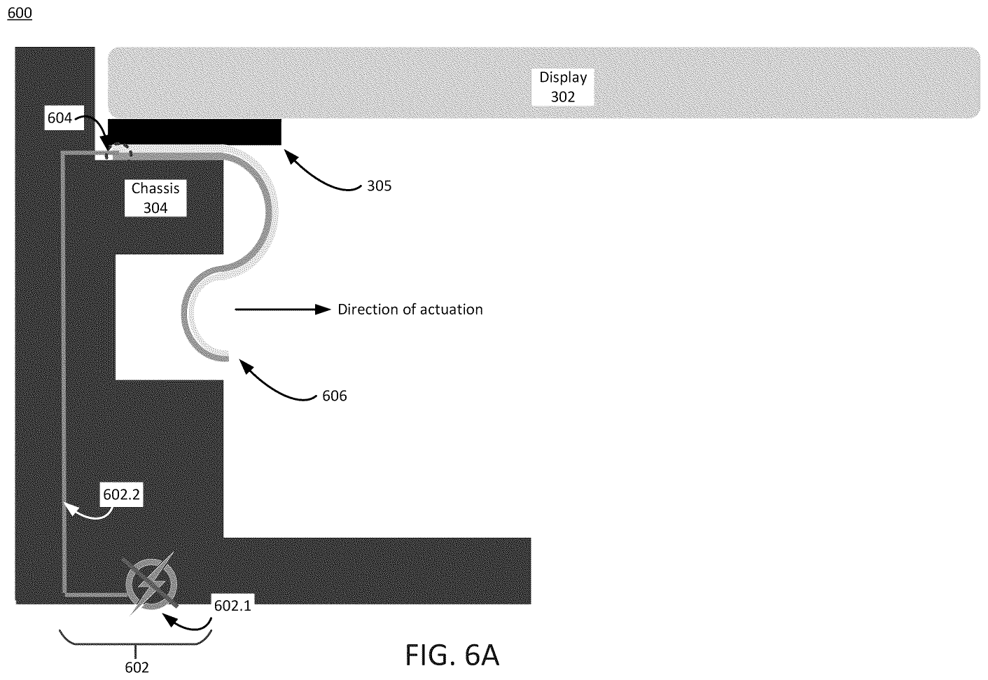

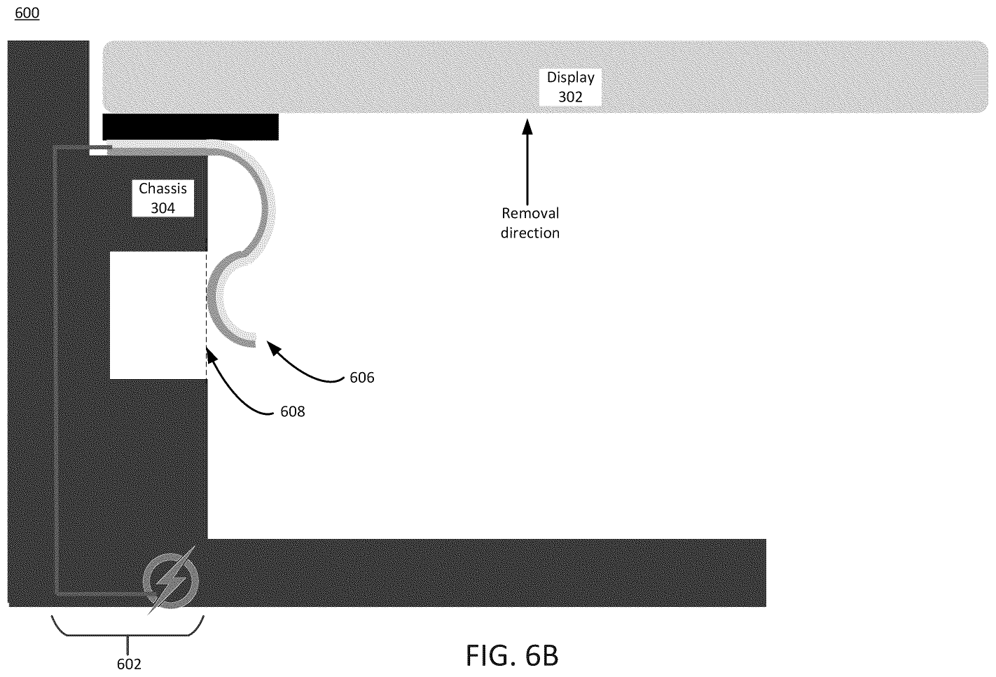

FIGS. 6A and 6B illustrate the use of a direct heating element in an off and an on state, respectively, in accordance with the disclosure. The electronic device 600 as shown in FIGS. 6A-6B may be identified with the electronic device 300 as discussed herein, and thus may include any suitable number of bimetal retaining mechanisms 606. The bimetal retaining mechanisms 606 may be identified with any of the bimetal retaining mechanisms as discussed herein, such as the bimetal retaining mechanisms 306, 346, the bimetal retaining mechanisms 403 included as part of the removable EMI cover 402, the bimetal retaining mechanisms 482, etc.

The electronic device 600 may further comprise any suitable number of direct heating elements 602, with one being shown in FIGS. 6A-6B for purposes of brevity. Each direct heating element 602 may be implemented as any suitable type and/or number of components, and is configured to selectively heat one or more of the bimetal retaining mechanisms 606 when predetermined conditions have been met, as discussed in further detail herein. Thus, the direct heating element 602 may be comprised of several components, such as a heat source 602.1 as shown in FIGS. 6A-6B, which is conductively coupled to one or more of the bimetal retaining mechanisms 606 via a coupling 602.2.

The heat source 602.1 may be implemented as any suitable type of component that is configured to heat one or more of the bimetal retaining mechanisms 606 to which the heat source 602.1 is coupled via the respective couplings 602.2. Thus, each direct heating element 602 may be configured to heat one or more of the bimetal retaining mechanisms 606 in the electronic device 300 in accordance with a one-to-one relationship or, alternatively, a direct heating element 602 may be configured to heat more than one bimetal retaining mechanism 606 via the use of a set of couplings 602.2 from a single heat source 602.1 to several bimetal retaining mechanism 606.

In any event, the heat source 602.1 may comprise a driving circuit and/or current source that is configured to drive current through the coupling 602.2 and into one or more of the bimetal retaining mechanisms 606. Thus, the coupling 602.2 may be electrically and conductively coupled to the bimetal retaining mechanism 606 via a connection 604, as shown in FIG. 6A. The connection 604 may be implemented as any suitable type of removable connection between the coupling 602.2 and each bimetal retaining mechanisms 606 to which the coupling 602.2 is connected. To provide some illustrative and non-limiting scenarios, the connection 604 may comprise any suitable type of connection that ensures that the coupling 602.2 remains in contact with the bimetal retaining mechanism 606 when the display 302 is mounted and retained within the electronic device 300, but still allows for the removal of the display 302. Thus, instead of a fixed coupling, the connection 605 may comprise a spring-loaded connection with a mated contact on the bimetal retaining mechanism 606, a mechanically-biased terminal that contacts the bimetal retaining mechanism 606 when the display 302 is retained within the electronic device 300, one or more pogo pins, etc.

Regardless of the manner in which the heat source 602.1 is coupled to the bimetal retaining mechanism 606, the heat source 602.1 is configured to drive current into one or more coupled bimetal retaining mechanism 606. Each coupled bimetal retaining mechanism 606 is thus heated as a result of resistive loss when the current source 602.1 is in the on state as shown in FIG. 6B. As noted above for the indirect heating, the direct heating element 602 may likewise transition between the off state as shown in FIG. 6A and the on state as shown in FIG. 6B in response to received control signals. Thus, the predetermined conditions may comprise user input that is provided in various ways, as discussed in further detail below.

In any event, each direct heating element 602 is configured, when activated, to heat one or more coupled bimetal retaining mechanisms 606 in excess of a predetermined threshold temperature. In response, each bimetal retaining mechanism 606 may be actuated in a direction of actuation, as shown in FIG. 6B, which illustrates the direct heating element 602 in the on state and the corresponding actuated mechanical position of the bimetal retaining mechanism 606. As shown in FIG. 6B, upon actuation of the bimetal retaining mechanism 606, the hook portion once again “clears” the chassis 304 in the vertical direction as shown by the reference line 608, which allows for the removal of the display 302 in the removal direction as shown.

VI. Extended Implementation of Internal Heating Systems and Bimetal Retaining Systems

The heating systems as described herein be implemented in accordance with any of the various bimetal retaining mechanisms as discussed herein, as well as alternative bimetal retaining systems. To provide some non-limiting and illustrative scenarios, the direct and indirect heating systems as described above with respect to FIGS. 5A-5B and 6A-6B may be implemented as part of any suitable type of electronic device, and may be implemented to heat any suitable type of bimetal retaining mechanisms such as the bimetal retaining mechanisms 202 as described with reference to FIG. 2A, the bimetal retaining mechanisms 306, 346 as described with respect to FIGS. 3A and 3B, the bimetal retaining mechanisms 403 as described with respect to FITG. 4A, the bimetal retaining mechanisms 482 as described with respect to FIGS. 4B and 4C, etc.

Furthermore, the bimetal retaining mechanisms as described herein may be partially or fully implemented as part of any suitable type of retaining assembly, which may be used to provide temperature-selective mechanical retainment of any suitable type of electronic component as discussed herein as well as alternative electronic components. Thus, any of the bimetal retaining mechanisms as described herein may be used as the entirety of a retaining assembly, such as one that implements bimetal strips and is disposed on all four sides of a display of an electronic device. However, any of any of the bimetal retaining mechanisms as described herein may alternatively be used as a portion of a retaining assembly. As an illustrative and non-limiting scenario, this may comprise the use of bimetal retaining mechanisms in strips that are disposed on less than four sides of a display, such as two or three sides. To provide another illustrative and non-limiting scenario, the bimetal retaining mechanisms as described herein may be implemented at predetermined locations of a retaining assembly, whereas other locations of the retaining assembly may comprise standard or non-bimetal retaining mechanisms. Such implementations may advantageously allow for a reduced number of bimetal retaining mechanisms and/or heating systems while still providing some assistance with respect to the removal of an electronic component as needed.

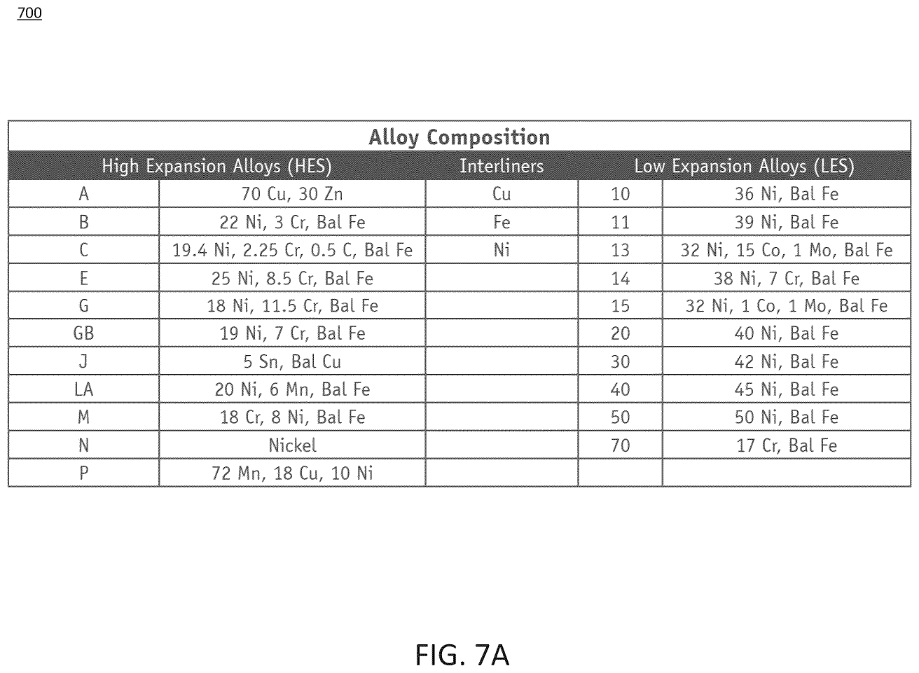

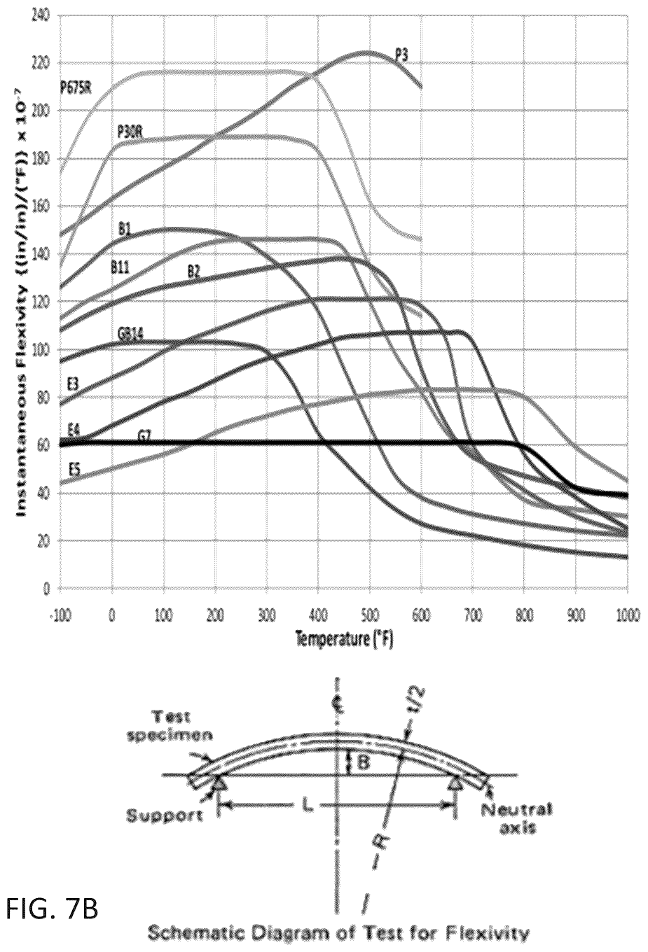

The bimetal retaining mechanisms as described herein may be implemented in accordance with any suitable type of bimetal compositions, which may include various known compositions as shown in FIG. 7A. The magnitude of the difference between the coefficients of thermal expansion of the different metals allows for bimetals to be manufactured having varying degrees of mechanical actuation, and thus are classified as high expansion or low expansion alloys as shown. The bimetal retaining mechanisms as described herein may utilize any of these alloys depending upon a required specification, which may be driven by cost, the mechanical design of the electronic device, the amount of mechanical actuation needed, the transition temperature, the type of electronic components being retained, etc.

It is noted that bimetals are associated with a property known as flexivity, which is defined as the change of curvature of the longitudinal center line of the specimen per unit temperature change for unit thickness, and is given by Equation 1 below as follows:

$$\\ \begin{matrix}F = \frac{( \frac{1}{{R}_{2}} - \frac{1}{{R}_{1}} ) t}{{T}_{2} - {T}_{1}} , & Eqn . 1\end{matrix}$$

thus for a simple beam, Equation 2 is provided as follows:

$$\\ \begin{matrix}\frac{1}{R} = \frac{8 B}{{L}^{2} + 4 Bt + 4 {B}^{{}^{} 2}} & Eqn . 2\end{matrix}$$

The variables as shown in Equations 1 and 2 above are summarized in accordance with Table 1 below:

TABLE 1

| | |
|---|---|
| F | Flexivity |
| R₁ and R₂ | Radii of curve |
| T₁ and T₂ | Temperature (° F.) |
| t | Thickness (in.) |
| B | Movement (in.) |
| L | Distance between support points (in.) |

The variables are also illustrated via the inset schematic diagram shown in FIG. 7B.

Moreover, to demonstrate the varying flexivity among the different bimetal compositions, FIG. 7B illustrates a graph of flexivity versus thermal deflection for various bimetal alloys, in accordance with the disclosure. It is noted that the units used are inches per degree Fahrenheit. For many thermostatic bimetals, the flexivity over a 50° F. to 200° F. temperature range varies from 0.21×10⁻⁷ for Truflex 1513 to 215×10⁻⁷ for Truflex P675R, which is the most active. While a few thermostatic bimetal types have a flexivity that is linear with temperature, most have a non-linear flexivity that is at its highest value over a limited temperature range.

VII. An Electronic Device

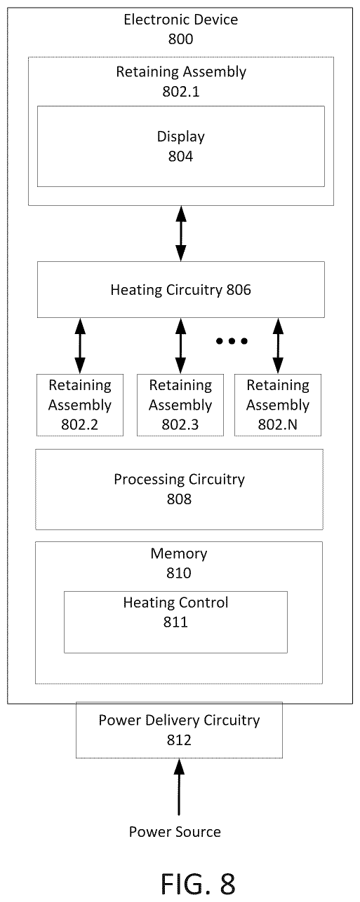

FIG. 8 illustrates an electronic device, in accordance with the disclosure. The electronic device 800 may be identified with any suitable type of device that implements the bimetal retaining mechanisms and/or heating systems as discussed herein. The electronic device 800 may be identified with the electronic device 300 as discussed herein, or any other suitable type of electronic device in which temperature-selective electronic component retainment is utilized. Thus, the electronic device 800 may be identified with a wireless device, a user equipment (UE), a mobile phone, a laptop computer, a tablet, a wearable device, etc.

The electronic device 800 may comprise a display 804, which forms part of a display assembly as discussed above. The display 802 may be identified with the display 302 as described herein. The display 802 may be implemented as or form part of any suitable type of display assembly such as a light-emitting diode (LED) display, a liquid crystal display (LDC), an organic LED display, a Twisted Nematic (TN) display, an In-Plane Switching (IPS) display, etc.

The electronic device 800 comprises any suitable number N of retaining assemblies 802.1-802.N. These retaining assemblies 802.1-802.N may be implemented to provide temperature-selective retainment of any suitable type of electronic components of the electronic device 800, such as the display 804 as discussed herein. The electronic device 800 may comprise additional or alternate display assemblies 802.2-802.N, each being identified with the retainment of a different electronic component. Thus, the retaining assemblies 802.1-802.N may be identified with the retaining assembly 382, the removable EMI cover 402, one or more of the bimetal retaining mechanisms 306, 346, 482, etc. Each retaining assembly 802.1-802.N is configured to release a respectively coupled electronic component (such as the display 804) when the bimetal retaining mechanisms associated therewith are heated in excess of a predetermined threshold temperature, as discussed above. The electronic components associated with the retaining assemblies 802.2-802.N are not shown for purposes of brevity, but may comprise any suitable type of electronic components as discussed herein.

The electronic device 800 optionally comprises heating circuitry 806, which may be identified with any of the direct and/or indirect heating systems as discussed herein. Thus, the heating circuitry 806 may be identified with the indirect heating elements 502 as discussed above with respect to FIGS. 5A-5B, the direct heating elements 602 as discussed above with respect to FIGS. 6A-6B, etc.

The power delivery circuitry 812 may comprise part of universal serial bus (USB) power delivery circuitry that is used to supply power to and/or charge a battery of the electronic device 800. Thus, the power delivery circuitry 812 may include any suitable type of power management circuitry, power conditioners, etc., and may be configured to selectively provide power to the electronic device 800 via the external power source or the battery of the electronic device 800. The direct heating circuitry 806 may be coupled to and/or utilize power delivered via any suitable components of the electronic device 800, which may include the power delivery circuitry 812.

The electronics device 800 may further comprise processing circuitry 808, which may be configured as any suitable number and/or type of computer processors, and which may function to control the electronic device 800 and/or other components of the electronic device 800, such as the heating circuitry 806. The processing circuitry 808 may be identified with one or more processors (or suitable portions thereof) implemented by the electronic device 800. The processing circuitry 808 may be identified with one or more processors such as a host processor, a digital signal processor, one or more microprocessors, a central processing unit (CPU), graphics processors such as a graphics processing unit (GPU), baseband processors, microcontrollers, an application-specific integrated circuit (ASIC), part (or the entirety of) a field-programmable gate array (FPGA), etc.

The processing circuitry 808 may be configured to carry out instructions to perform arithmetical, logical, and/or input/output (I/O) operations, and/or to control the operation of one or more components of electronic device 800 to perform various functions as described herein. The processing circuitry 808 may include one or more microprocessor cores, memory registers, buffers, clocks, etc., and may generate electronic control signals associated with the components of the electronic device 800 to control and/or modify the operation of these components. The processing circuitry 808 may communicate with and/or control functions associated with the memory 810, as well as any other components of the electronic device 808. Thus, the processing circuitry 808 may generate control signals or cause other components to generate such control signals to place the heating circuitry 806 in an on or off state in response to one or more predetermined conditions being met, as discussed herein.

The memory 810 stores data and/or instructions such that, when executed by the processing circuitry 808, cause the electronic device 800 to perform various functions such as controlling, monitoring, and/or regulating the operation of the electronic device 800, providing data to the display 804 to be displayed, generating the control signals for the operation of the heating circuitry 806, etc., as discussed in further detail herein. The memory 810 may be implemented as any suitable type of volatile and/or non-volatile memory, including read-only memory (ROM), random access memory (RAM), flash memory, a magnetic storage media, an optical disc, erasable programmable read only memory (EPROM), programmable read only memory (PROM), etc. The memory 810 may be non-removable, removable, or a combination of both. The memory 810 may be implemented as a non-transitory computer readable medium storing one or more executable instructions such as logic, algorithms, code, etc. The instructions, logic, code, etc., stored in the memory 810 are represented by the various modules as shown. The processing circuitry 808 may execute the instructions stored in the memory 810, which are represented as the various modules and further discussed below, to enable any of the techniques as described herein to be functionally realized.

The heating control module 811 may store computer-readable instructions that, when executed by the processing circuitry 808, enable the processing circuitry 808 to perform any of the functions as described herein with respect to the control of the on and off state of the heating circuitry 806. Thus, the processing circuitry 808 may execute the instructions stored in the heating control module 811 to receive input data from any suitable components of the electronic device 800, to determine whether one or more predetermined conditions have been met, to generate control signals to switch the heating circuitry 806 into the on and off states, etc.

The predetermined conditions that, when satisfied, result in the heating circuitry 806 being switched into the on or off state may comprise any suitable conditions that are used to control the heating of the bimetal retaining mechanisms as discussed herein. To provide some non-limiting and illustrative scenarios, the predetermined conditions may comprise user input that identifies that the heating circuitry 806 should be switched on to initiate heating. This user input may be provided via an operating system of the electronic device, or a lower-level user interface such as a bootup or BIOS menu option. The user input may also represent a combination of button presses (such as a specific order, holding buttons down in excess of a threshold period of time, etc.), a dedicated switch, etc., that is recognized via the processing circuitry 808. The predetermined conditions that return the heating circuitry to an off state may also comprise user input, a threshold “timeout” period being exceeded, the use of temperature sensors that indicate a predetermined temperature has been exceeded, etc.

VIII. A Process Flow

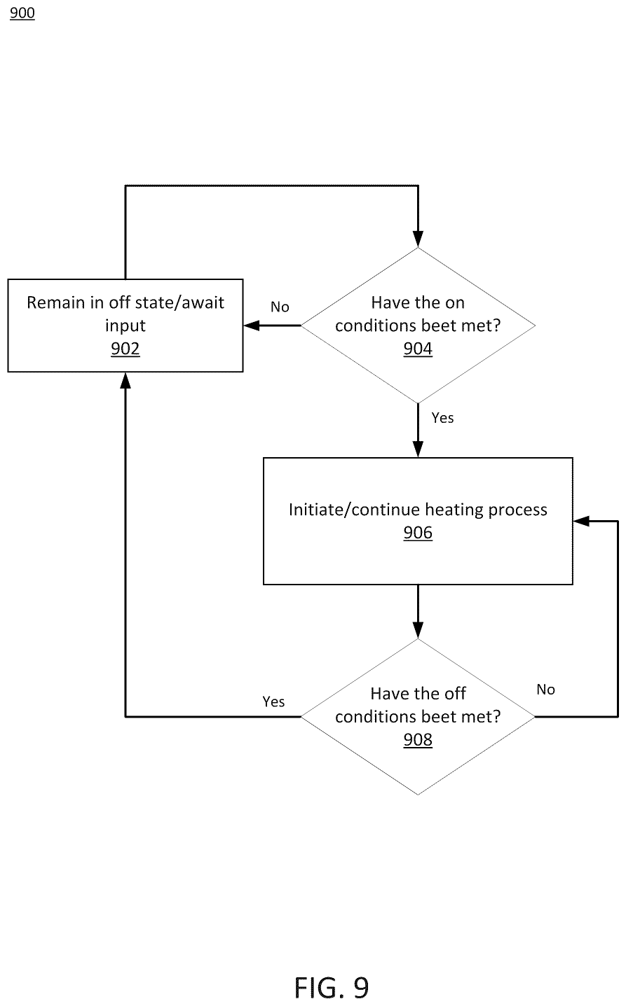

FIG. 9 illustrates a process flow, in accordance with the disclosure. With reference to FIG. 9, the flow 900 may comprise a process flow that is executed by and/or otherwise associated with one or more processors and/or components identified with any suitable electronic device. The one or more processors and/or components may be identified with the processing circuitry 808 and/or the heating circuitry 806 as discussed herein with respect to FIG. 8, and may be implemented via one or more processors executing instructions stored on any suitable computer-readable storage medium, such as the memory 810. The flow 900 may include alternate or additional processes that are not shown for purposes of brevity, and may be performed in a different order than those shown.

Flow 900 may begin in a default state (block 902) in which the heating circuitry 806 is in the off state. This may include, in various non-limiting and illustrative scenarios, the processing circuitry 808 being in a state that is periodically or continuously monitoring and/or receiving input data (or waiting to receive such input data), and the heating circuitry 806 likewise being in a state ready to receive control signals to transition to the on state.

The flow 900 may further comprise determining (block 904) whether predetermined conditions have been met that are associated with a transition of the heating circuitry 806 to the on state. As noted above, this may include receiving user input or any other suitable type of input that indicates that the heating circuitry 806 is to be activated. Such input may be received, in various non-limiting and illustrative scenarios, during a repair or servicing of an electronic device in which the bimetal retaining mechanisms are to be heated to cause mechanical actuation, as noted above.

If the predetermined conditions have been met (block 904, Yes), then the process flow may proceed to block 906. However, if the predetermined conditions are not met (block 904, No), then the heating circuitry 806 may remain in the default state (block 902). Thus, the process flow 900 remains in a monitoring “loop” represented by the blocks 902, 904 until the predetermined on conditions have been met.

Once the predetermined on conditions have been met, the process flow 900 comprises initiating (block 906) the heating process by activation of the heating circuitry 806. That is, the heating circuitry 806 is transitioned to the on state in which the bimetal retaining mechanisms are heated, as described above. Again, this heating process may be performed via any suitable means, such as the direct or indirect heating elements described herein.

The process flow 900 then continued to determine (block 908) whether predetermined conditions have been met that are associated with a transition of the heating circuitry 806 to an off state. Again, this may include receiving user input or any other suitable type of input that indicates that the heating circuitry 806 is to be deactivated. Such input may comprise a predetermined threshold time period elapsing and/or a temperature sensor indicating that a monitored temperature of the bimetal retaining mechanism and/or a region proximate to the bimetal retaining mechanism has exceeded a predetermined threshold deactivation temperature.

If the predetermined off conditions are met (block 908, Yes), then the process flow 900 may revert back to the default state (block 902) in which the heating circuitry 806 is in the off state. However, if the predetermined conditions are not met (block 908, No), then the heating circuitry 806 may remain in the on state (block 906). Thus, the process flow 900 remains in a heating “loop” represented by the blocks 906, 908 until the predetermined off conditions have been met.

IX. General Configuration of an Electronic Device

An electronic device is provided. The electronic device comprises an electronic component and a retaining assembly fixedly coupled to the electronic component. The retaining assembly comprises a plurality of bimetal retaining mechanisms configured to retain the electronic component to the electronic device via a fitted arrangement between the plurality of bimetal retaining mechanisms and a mechanical structure of the electronic device when a temperature of the plurality of bimetal retaining mechanisms is less than a predetermined threshold temperature. The plurality of bimetal retaining mechanisms are configured, when heated to a temperature that is greater than the predetermined threshold temperature, to be released from the mechanical structure of the electronic device to thereby enable removal of the electronic component from the electronic device. In addition or in alternative to and in any combination with the optional features previously explained in this paragraph, the electronic component comprises a display. In addition or in alternative to and in any combination with the optional features previously explained in this paragraph, the retaining assembly comprises one or more bimetal strips, and the plurality of bimetal retaining mechanisms are formed as part of the one or more bimetal strips. In addition or in alternative to and in any combination with the optional features previously explained in this paragraph, each one of the plurality of bimetal retaining mechanisms comprises a hook configured to provide the fitted arrangement between the plurality of bimetal retaining mechanisms and the mechanical structure of the electronic device via a snap-fit mechanical engagement between each respective hook and the mechanical structure. In addition or in alternative to and in any combination with the optional features previously explained in this paragraph, each one of the plurality of bimetal retaining mechanisms comprises a snap-hook configured to provide the fitted arrangement between the plurality of bimetal retaining mechanisms and the mechanical structure of the electronic device via a snap fit mechanical engagement between each respective snap-hook and the mechanical structure. In addition or in alternative to and in any combination with the optional features previously explained in this paragraph, the fitted arrangement between the plurality of bimetal retaining mechanisms and the mechanical structure of the electronic device is maintained by way of a release angle between a portion of each respective one of the plurality of bimetal retaining mechanisms and the mechanical structure of the electronic device being less than a threshold release angle. In addition or in alternative to and in any combination with the optional features previously explained in this paragraph, when heated in excess of the predetermined threshold temperature, the respective release angle of the portion of each one of the plurality of bimetal retaining mechanisms is increased to greater than the threshold release angle as a result of mechanical actuation. In addition or in alternative to and in any combination with the optional features previously explained in this paragraph, the electronic device further includes one or more heating elements configured to generate heat in response to a predetermined condition being met to heat the plurality of bimetal retaining mechanisms to a temperature that is greater than the predetermined threshold temperature. In addition or in alternative to and in any combination with the optional features previously explained in this paragraph, the electronic device further includes one or more heating elements configured to generate heat in response to a predetermined condition being met to heat the plurality of bimetal retaining mechanisms to a temperature that is greater than the predetermined threshold temperature. In addition or in alternative to and in any combination with the optional features previously explained in this paragraph, the predetermined condition comprises user input received via the electronic device. In addition or in alternative to and in any combination with the optional features previously explained in this paragraph, the one or more heating elements are coupled to the mechanical structure of the electronic device and are configured to provide indirect heating to the plurality of bimetal retaining mechanisms. In addition or in alternative to and in any combination with the optional features previously explained in this paragraph, the one or more heating elements comprise a current source that is conductively coupled to the plurality of bimetal retaining mechanisms and are configured to heat the plurality of bimetal retaining mechanisms via current driving. addition or in alternative to and in any combination with the optional features previously explained in this paragraph, the plurality of bimetal retaining mechanisms comprise a first material having a first coefficient of thermal expansion and a second material having a second coefficient of thermal expansion, the first coefficient of thermal expansion is less than the second coefficient of thermal expansion, and the fitted arrangement between the plurality of bimetal retaining mechanisms and the mechanical structure of the electronic device comprises the second material of each of the plurality of bimetal retaining mechanisms being disposed towards the mechanical structure.

X. General Configuration of a Temperature-Selective Mechanical Retaining Assembly

A temperature-selective mechanical retaining assembly is provided. The temperature-selective mechanical retaining assembly comprises a plurality of bimetal retaining mechanisms fixedly coupled to a first electronic component of an electronic device, and a second electronic component coupled to the first electronic component via a fitted arrangement between the plurality of bimetal retaining mechanisms and the second electronic component when a temperature of the plurality of bimetal retaining mechanisms is less than a predetermined threshold temperature. The plurality of bimetal retaining mechanisms are configured, when heated to a temperature that is greater than the predetermined threshold temperature, to be released from the second electronic component to thereby enable removal of the second electronic component from the first electronic component of the electronic device. In addition or in alternative to and in any combination with the optional features previously explained in this paragraph, the first electronic component comprises a printed circuit board (PCB). In addition or in alternative to and in any combination with the optional features previously explained in this paragraph, the second electronic component comprises an electromagnetic interference (EMI) shield. In addition or in alternative to and in any combination with the optional features previously explained in this paragraph, the bimetal retaining mechanisms comprise bimetal clips. In addition or in alternative to and in any combination with the optional features previously explained in this paragraph, the electronic component further comprises a heating element configured to generate heat in response to a predetermined condition being met to heat one or more of the plurality of bimetal retaining mechanisms to a temperature that is greater than the predetermined threshold temperature.

XI. General Configuration of an Electromagnetic Interference (EMI) Shield Assembly

An electromagnetic interference (EMI) shield assembly is provided. The EMI shield assembly comprises a removable EMI cover comprising a plurality of bimetal retaining mechanisms, and an EMI housing coupled to the removable EMI cover via a fitted arrangement between the plurality of bimetal retaining mechanisms and the removable EMI cover when a temperature of the plurality of bimetal retaining mechanisms is less than a predetermined threshold temperature. The plurality of bimetal retaining mechanisms are configured, when heated to a temperature that is greater than the predetermined threshold temperature, to be released from the EMI housing to thereby enable removal of the removable EMI cover from the EMI housing. In addition or in alternative to and in any combination with the optional features previously explained in this paragraph, the EMI shield assembly is part of an electronic device comprising a heating element configured to generate heat in response to a predetermined condition being met to heat one or more of the plurality of bimetal retaining mechanisms to a temperature that is greater than the predetermined threshold temperature.

### EXAMPLES

The following examples pertain to various techniques of the present disclosure.

An example (e.g. example 1) is directed to an electronic device, comprising: an electronic component; and a retaining assembly fixedly coupled to the electronic component, wherein the retaining assembly comprises a plurality of bimetal retaining mechanisms configured to retain the electronic component to the electronic device via a fitted arrangement between the plurality of bimetal retaining mechanisms and a mechanical structure of the electronic device when a temperature of the plurality of bimetal retaining mechanisms is less than a predetermined threshold temperature, and wherein the plurality of bimetal retaining mechanisms are configured, when heated to a temperature that is greater than the predetermined threshold temperature, to be released from the mechanical structure of the electronic device to thereby enable removal of the electronic component from the electronic device.

Another example (e.g. example 2), relates to a previously-described example (e.g. example 1), wherein the electronic component comprises a display.

Another example (e.g. example 3) relates to a previously-described example (e.g. one or more of examples 1-2), wherein the retaining assembly comprises one or more bimetal strips, and wherein the plurality of bimetal retaining mechanisms are formed as part of the one or more bimetal strips.

Another example (e.g. example 4) relates to a previously-described example (e.g. one or more of examples 1-3), wherein each one of the plurality of bimetal retaining mechanisms comprises a hook configured to provide the fitted arrangement between the plurality of bimetal retaining mechanisms and the mechanical structure of the electronic device via a snap-fit mechanical engagement between each respective hook and the mechanical structure.

Another example (e.g. example 5) relates to a previously-described example (e.g. one or more of examples 1-4), wherein each one of the plurality of bimetal retaining mechanisms comprises a snap-hook configured to provide the fitted arrangement between the plurality of bimetal retaining mechanisms and the mechanical structure of the electronic device via a snap fit mechanical engagement between each respective snap-hook and the mechanical structure.

Another example (e.g. example 6) relates to a previously-described example (e.g. one or more of examples 1-5), wherein the fitted arrangement between the plurality of bimetal retaining mechanisms and the mechanical structure of the electronic device is maintained by way of a release angle between a portion of each respective one of the plurality of bimetal retaining mechanisms and the mechanical structure of the electronic device being less than a threshold release angle.

Another example (e.g. example 7) relates to a previously-described example (e.g. one or more of examples 1-6), wherein, when heated in excess of the predetermined threshold temperature, the respective release angle of the portion of each one of the plurality of bimetal retaining mechanisms is increased to greater than the threshold release angle as a result of mechanical actuation.

Another example (e.g. example 8) relates to a previously-described example (e.g. one or more of examples 1-7), further comprising: one or more heating elements configured to generate heat in response to a predetermined condition being met to heat the plurality of bimetal retaining mechanisms to a temperature that is greater than the predetermined threshold temperature.

Another example (e.g. example 9) relates to a previously-described example (e.g. one or more of examples 1-8), further comprising: one or more heating elements configured to generate heat in response to a predetermined condition being met to heat the plurality of bimetal retaining mechanisms to a temperature that is greater than the predetermined threshold temperature.

Another example (e.g. example 10) relates to a previously-described example (e.g. one or more of examples 1-9), wherein the predetermined condition comprises user input received via the electronic device.

Another example (e.g. example 11) relates to a previously-described example (e.g. one or more of examples 1-10), wherein the one or more heating elements are coupled to the mechanical structure of the electronic device and are configured to provide indirect heating to the plurality of bimetal retaining mechanisms.

Another example (e.g. example 12) relates to a previously-described example (e.g. one or more of examples 1-11), wherein the one or more heating elements comprise a current source that is conductively coupled to the plurality of bimetal retaining mechanisms and are configured to heat the plurality of bimetal retaining mechanisms via current driving.

Another example (e.g. example 13) relates to a previously-described example (e.g. one or more of examples 1-12), wherein: the plurality of bimetal retaining mechanisms comprise a first material having a first coefficient of thermal expansion and a second material having a second coefficient of thermal expansion, the first coefficient of thermal expansion is less than the second coefficient of thermal expansion, and the fitted arrangement between the plurality of bimetal retaining mechanisms and the mechanical structure of the electronic device comprises the second material of each of the plurality of bimetal retaining mechanisms being disposed towards the mechanical structure.

An example (e.g. example 14) is directed to a temperature-selective mechanical retaining assembly, comprising: a plurality of bimetal retaining mechanisms fixedly coupled to a first electronic component of an electronic device; and a second electronic component coupled to the first electronic component via a fitted arrangement between the plurality of bimetal retaining mechanisms and the second electronic component when a temperature of the plurality of bimetal retaining mechanisms is less than a predetermined threshold temperature, wherein the plurality of bimetal retaining mechanisms are configured, when heated to a temperature that is greater than the predetermined threshold temperature, to be released from the second electronic component to thereby enable removal of the second electronic component from the first electronic component of the electronic device.

Another example (e.g. example 15), relates to a previously-described example (e.g. example 14), wherein the first electronic component comprises a printed circuit board (PCB).

Another example (e.g. example 16) relates to a previously-described example (e.g. one or more of examples 14-15), wherein the second electronic component comprises an electromagnetic interference (EMI) shield.

Another example (e.g. example 17) relates to a previously-described example (e.g. one or more of examples 14-16), wherein the bimetal retaining mechanisms comprise bimetal clips.

Another example (e.g. example 18) relates to a previously-described example (e.g. one or more of examples 14-17), wherein the electronic component further comprises a heating element configured to generate heat in response to a predetermined condition being met to heat one or more of the plurality of bimetal retaining mechanisms to a temperature that is greater than the predetermined threshold temperature.

An example (e.g. example 19) is directed to an electromagnetic interference (EMI) shield assembly, comprising: a removable EMI cover comprising a plurality of bimetal retaining mechanisms; and an EMI housing coupled to the removable EMI cover via a fitted arrangement between the plurality of bimetal retaining mechanisms and the removable EMI cover when a temperature of the plurality of bimetal retaining mechanisms is less than a predetermined threshold temperature, wherein the plurality of bimetal retaining mechanisms are configured, when heated to a temperature that is greater than the predetermined threshold temperature, to be released from the EMI housing to thereby enable removal of the removable EMI cover from the EMI housing.

Another example (e.g. example 20) relates to a previously-described example (e.g. example 19), wherein the EMI shield assembly is part of an electronic device comprising a heating element configured to generate heat in response to a predetermined condition being met to heat one or more of the plurality of bimetal retaining mechanisms to a temperature that is greater than the predetermined threshold temperature.

An example (e.g. example 21) is directed to an electronic device, comprising: an electronic component; and a retaining means fixedly coupled to the electronic component, wherein the retaining means comprises a plurality of bimetal retaining means for retaining the electronic component to the electronic device via a fitted arrangement between the plurality of bimetal retaining means and a mechanical structure of the electronic device when a temperature of the plurality of bimetal retaining means is less than a predetermined threshold temperature, and wherein the plurality of bimetal retaining means, when heated to a temperature that is greater than the predetermined threshold temperature, are released from the mechanical structure of the electronic device to thereby enable removal of the electronic component from the electronic device.

Another example (e.g. example 22), relates to a previously-described example (e.g. example 21), wherein the electronic component comprises a display.

Another example (e.g. example 23) relates to a previously-described example (e.g. one or more of examples 21-22), wherein the retaining means comprises one or more bimetal strips, and wherein the plurality of bimetal retaining means are formed as part of the one or more bimetal strips.

Another example (e.g. example 24) relates to a previously-described example (e.g. one or more of examples 21-23), wherein each one of the plurality of bimetal retaining means comprises a hook configured to provide the fitted arrangement between the plurality of bimetal retaining means and the mechanical structure of the electronic device via a snap-fit mechanical engagement between each respective hook and the mechanical structure.

Another example (e.g. example 25) relates to a previously-described example (e.g. one or more of examples 21-24), wherein each one of the plurality of bimetal retaining means comprises a snap-hook configured to provide the fitted arrangement between the plurality of bimetal retaining means and the mechanical structure of the electronic device via a snap fit mechanical engagement between each respective snap-hook and the mechanical structure.

Another example (e.g. example 26) relates to a previously-described example (e.g. one or more of examples 21-25), wherein the fitted arrangement between the plurality of bimetal retaining means and the mechanical structure of the electronic device is maintained by way of a release angle between a portion of each respective one of the plurality of bimetal retaining means and the mechanical structure of the electronic device being less than a threshold release angle.

Another example (e.g. example 27) relates to a previously-described example (e.g. one or more of examples 21-26), wherein, when heated in excess of the predetermined threshold temperature, the respective release angle of the portion of each one of the plurality of bimetal retaining means is increased to greater than the threshold release angle as a result of mechanical actuation.

Another example (e.g. example 28) relates to a previously-described example (e.g. one or more of examples 21-27), further comprising: one or more heating means configured to generate heat in response to a predetermined condition being met to heat the plurality of bimetal retaining means to a temperature that is greater than the predetermined threshold temperature.

Another example (e.g. example 29) relates to a previously-described example (e.g. one or more of examples 21-28), further comprising: one or more heating means configured to generate heat in response to a predetermined condition being met to heat the plurality of bimetal retaining means to a temperature that is greater than the predetermined threshold temperature.

Another example (e.g. example 30) relates to a previously-described example (e.g. one or more of examples 21-29), wherein the predetermined condition comprises user input received via the electronic device.

Another example (e.g. example 31) relates to a previously-described example (e.g. one or more of examples 21-30), wherein the one or more heating means are coupled to the mechanical structure of the electronic device and are configured to provide indirect heating to the plurality of bimetal retaining means.

Another example (e.g. example 32) relates to a previously-described example (e.g. one or more of examples 21-31), wherein the one or more heating means comprise a current source that is conductively coupled to the plurality of bimetal retaining means and are configured to heat the plurality of bimetal retaining means via current driving.

Another example (e.g. example 33) relates to a previously-described example (e.g. one or more of examples 21-32), wherein: the plurality of bimetal retaining means comprise a first material having a first coefficient of thermal expansion and a second material having a second coefficient of thermal expansion, the first coefficient of thermal expansion is less than the second coefficient of thermal expansion, and the fitted arrangement between the plurality of bimetal retaining means and the mechanical structure of the electronic device comprises the second material of each of the plurality of bimetal retaining means being disposed towards the mechanical structure.

An example (e.g. example 34) is directed to a temperature-selective mechanical retaining means, comprising: a plurality of bimetal retaining means fixedly coupled to a first electronic component of an electronic device; and a second electronic component coupled to the first electronic component via a fitted arrangement between the plurality of bimetal retaining means and the second electronic component when a temperature of the plurality of bimetal retaining means is less than a predetermined threshold temperature, wherein the plurality of bimetal retaining means, when heated to a temperature that is greater than the predetermined threshold temperature, are released from the second electronic component to thereby enable removal of the second electronic component from the first electronic component of the electronic device.

Another example (e.g. example 35), relates to a previously-described example (e.g. example 34), wherein the first electronic component comprises a printed circuit board (PCB).

Another example (e.g. example 36) relates to a previously-described example (e.g. one or more of examples 34-35), wherein the second electronic component comprises an electromagnetic interference (EMI) shield.

Another example (e.g. example 37) relates to a previously-described example (e.g. one or more of examples 34-36), wherein the bimetal retaining means comprise bimetal clips.

Another example (e.g. example 38) relates to a previously-described example (e.g. one or more of examples 34-37), wherein the electronic component further comprises a heating means configured to generate heat in response to a predetermined condition being met to heat one or more of the plurality of bimetal retaining means to a temperature that is greater than the predetermined threshold temperature.

An example (e.g. example 39) is directed to an electromagnetic interference (EMI) shield assembly, comprising: a removable EMI cover comprising a plurality of bimetal retaining means; and an EMI housing coupled to the removable EMI cover via a fitted arrangement between the plurality of bimetal retaining means and the removable EMI cover when a temperature of the plurality of bimetal retaining means is less than a predetermined threshold temperature, wherein the plurality of bimetal retaining means, when heated to a temperature that is greater than the predetermined threshold temperature, are released from the EMI housing to thereby enable removal of the removable EMI cover from the EMI housing.

Another example (e.g. example 40) relates to a previously-described example (e.g. example 39), wherein the EMI shield assembly is part of an electronic device comprising a heating means configured to generate heat in response to a predetermined condition being met to heat one or more of the plurality of bimetal retaining means to a temperature that is greater than the predetermined threshold temperature.

An apparatus as shown and described.

A method as shown and described.

### CONCLUSION

The aforementioned description will so fully reveal the general nature of the implementation of the disclosure that others can, by applying knowledge within the skill of the art, readily modify and/or adapt for various applications such specific implementations without undue experimentation and without departing from the general concept of the present disclosure. Therefore, such adaptations and modifications are intended to be within the meaning and range of equivalents of the disclosed implementations, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

Each implementation described may include a particular feature, structure, or characteristic, but every implementation may not necessarily include the particular feature, structure, or characteristic. Moreover, such phrases are not necessarily referring to the same implementation. Further, when a particular feature, structure, or characteristic is described in connection with an implementation, it is submitted that it is within the knowledge of one skilled in the art to affect such feature, structure, or characteristic in connection with other implementations whether or not explicitly described.

The exemplary implementations described herein are provided for illustrative purposes, and are not limiting. Other implementations are possible, and modifications may be made to the exemplary implementations. Therefore, the specification is not meant to limit the disclosure. Rather, the scope of the disclosure is defined only in accordance with the following claims and their equivalents.

Throughout the drawings, it should be noted that like reference numbers are used to depict the same or similar elements, features, and structures, unless otherwise noted.

The terms “at least one” and “one or more” may be understood to include a numerical quantity greater than or equal to one (e.g., one, two, three, four, [ . . . ], etc.). The term “a plurality” may be understood to include a numerical quantity greater than or equal to two (e.g., two, three, four, five, [ . . . ], etc.).

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. The terms “group (of)”, “set (of)”, “collection (of)”, “series (of)”, “sequence (of)”, “grouping (of)”, etc., and the like in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

The phrase “at least one of” with regard to a group of elements may be used herein to mean at least one element from the group consisting of the elements. The phrase “at least one of” with regard to a group of elements may be used herein to mean a selection of: one of the listed elements, a plurality of one of the listed elements, a plurality of individual listed elements, or a plurality of a multiple of individual listed elements.

What is claimed is:

1. An electronic device, comprising:
an electronic component; and
a retaining assembly fixedly coupled to the electronic component,
wherein the retaining assembly comprises a plurality of bimetal retaining mechanisms configured to retain the electronic component to the electronic device via a fitted arrangement between the plurality of bimetal retaining mechanisms and a mechanical structure of the electronic device when a temperature of the plurality of bimetal retaining mechanisms is less than a predetermined threshold temperature, and
wherein the plurality of bimetal retaining mechanisms are configured, when heated to a temperature that is greater than the predetermined threshold temperature, to be released from the mechanical structure of the electronic device to thereby enable removal of the electronic component from the electronic device.

2. The electronic device of claim 1, wherein the electronic component comprises a display.

3. The electronic device of claim 1, wherein the retaining assembly comprises one or more bimetal strips, and
wherein the plurality of bimetal retaining mechanisms are formed as part of the one or more bimetal strips.

4. The electronic device of claim 1, wherein each one of the plurality of bimetal retaining mechanisms comprises a hook configured to provide the fitted arrangement between the plurality of bimetal retaining mechanisms and the mechanical structure of the electronic device via a snap-fit mechanical engagement between each respective hook and the mechanical structure.

5. The electronic device of claim 1, wherein each one of the plurality of bimetal retaining mechanisms comprises a snap-hook configured to provide the fitted arrangement between the plurality of bimetal retaining mechanisms and the mechanical structure of the electronic device via a snap fit mechanical engagement between each respective snap-hook and the mechanical structure.

6. The electronic device of claim 1, wherein the fitted arrangement between the plurality of bimetal retaining mechanisms and the mechanical structure of the electronic device is maintained by way of a release angle between a portion of each respective one of the plurality of bimetal retaining mechanisms and the mechanical structure of the electronic device being less than a threshold release angle.

7. The electronic device of claim 6, wherein, when heated in excess of the predetermined threshold temperature, the respective release angle of the portion of each one of the plurality of bimetal retaining mechanisms is increased to greater than the threshold release angle as a result of mechanical actuation.

8. The electronic device of claim 1, further comprising:
one or more heating elements configured to generate heat in response to a predetermined condition being met to heat the plurality of bimetal retaining mechanisms to a temperature that is greater than the predetermined threshold temperature.

9. The electronic device of claim 1, further comprising:
one or more heating elements configured to generate heat in response to a predetermined condition being met to heat the plurality of bimetal retaining mechanisms to a temperature that is greater than the predetermined threshold temperature.

10. The electronic device of claim 9, wherein the predetermined condition comprises user input received via the electronic device.

11. The electronic device of claim 9, wherein the one or more heating elements are coupled to the mechanical structure of the electronic device and are configured to provide indirect heating to the plurality of bimetal retaining mechanisms.

12. The electronic device of claim 9, wherein the one or more heating elements comprise a current source that is conductively coupled to the plurality of bimetal retaining mechanisms and are configured to heat the plurality of bimetal retaining mechanisms via current driving.

13. The electronic device of claim 1, wherein:
the plurality of bimetal retaining mechanisms comprise a first material having a first coefficient of thermal expansion and a second material having a second coefficient of thermal expansion,
the first coefficient of thermal expansion is less than the second coefficient of thermal expansion, and
the fitted arrangement between the plurality of bimetal retaining mechanisms and the mechanical structure of the electronic device comprises the second material of each of the plurality of bimetal retaining mechanisms being disposed towards the mechanical structure.

14. A temperature-selective mechanical retaining assembly, comprising:
a plurality of bimetal retaining mechanisms fixedly coupled to a first electronic component of an electronic device; and
a second electronic component coupled to the first electronic component via a fitted arrangement between the plurality of bimetal retaining mechanisms and the second electronic component when a temperature of the plurality of bimetal retaining mechanisms is less than a predetermined threshold temperature,
wherein the plurality of bimetal retaining mechanisms are configured, when heated to a temperature that is greater than the predetermined threshold temperature, to be released from the second electronic component to thereby enable removal of the second electronic component from the first electronic component of the electronic device.

15. The temperature-selective mechanical retaining assembly of claim 14, wherein the first electronic component comprises a printed circuit board (PCB).

16. The temperature-selective mechanical retaining assembly of claim 14, wherein the second electronic component comprises an electromagnetic interference (EMI) shield.

17. The temperature-selective mechanical retaining assembly of claim 14, wherein the bimetal retaining mechanisms comprise bimetal clips.

18. The temperature-selective mechanical retaining assembly of claim 13, wherein the electronic component further comprises a heating element configured to generate heat in response to a predetermined condition being met to heat one or more of the plurality of bimetal retaining mechanisms to a temperature that is greater than the predetermined threshold temperature.

19. An electromagnetic interference (EMI) shield assembly, comprising:
a removable EMI cover comprising a plurality of bimetal retaining mechanisms; and
an EMI housing coupled to the removable EMI cover via a fitted arrangement between the plurality of bimetal retaining mechanisms and the removable EMI cover when a temperature of the plurality of bimetal retaining mechanisms is less than a predetermined threshold temperature,
wherein the plurality of bimetal retaining mechanisms are configured, when heated to a temperature that is greater than the predetermined threshold temperature, to be released from the EMI housing to thereby enable removal of the removable EMI cover from the EMI housing.

20. The EMI shield assembly of claim 19, wherein the EMI shield assembly is part of an electronic device comprising a heating element configured to generate heat in response to a predetermined condition being met to heat one or more of the plurality of bimetal retaining mechanisms to a temperature that is greater than the predetermined threshold temperature.
